(19) United States
(12) Patent Application Publication
(10) Pub. No.: US 2026/0202988 A1
(43) Pub. Date: Jul. 16, 2026

(54) MULTI-CHIP PACKAGE AND COMPUTING SYSTEM USING THE SAME

(71) Applicant: SK hynix Inc., Icheon-si Gyeonggi-do (KR)

(72) Inventors: Seong Ju LEE, San Jose, CA (US); Yangsoo PARK, San Jose, CA (US); Sunjoo KIM, San Jose, CA (US)

(73) Assignee: SK hynix Inc., Icheon-si Gyeonggi-do (KR)

(21) Appl. No.: 19/446,687

(22) Filed: Jan. 12, 2026

Related U.S. Application Data
(60) Provisional application No. 63/744,989, filed on Jan. 14, 2025.

(30) Foreign Application Priority Data
Dec. 8, 2025 (KR) 10-2025-0192895

(51) Int. Cl. G06F 3/06

(52) U.S. Cl. CPC G06F 3/0655; G06F 3/061; G06F 3/0679

(57) ABSTRACT

A computing system includes a host, a main memory, and a storage apparatus. During a first operation mode, the host accesses the main memory and the storage apparatus, respectively. During a second operation mode, the host directly moves data between the main memory and the storage apparatus.

### CROSS-REFERENCES TO RELATED APPLICATION

The present application claims benefit under 35 U.S.C. §119(e) to U.S. Provisional Application No. 63/744,989 filed on January 14, 2025 and claims priority under 35 U.S.C. §119(a) to Korean application number 10-2025-0192895 filed on December 8, 2025, in the Ministry of Intellectual Property, the entire contents of which applications are incorporated herein by reference.

### BACKGROUND

### 1.TECHNICAL FIELD

Various embodiments generally relate to integrated circuit technology, and, more particularly, to a multi-chip package and a computing system using the same.

### 2. RELATED ART

Because the storage provided in a mobile device has a relatively low bandwidth, it may be difficult to sufficiently support on-device artificial intelligence (AI) operations. For example, when a large language model (LLM) operation is performed on a smartphone, the low bandwidth of the storage may become an issue. When a user executes an LLM application, a computing system mounted in the smartphone moves data related to existing applications (e.g., YouTube, camera, etc.) that were being executed in the main memory (e.g., dynamic random access memory (DRAM)) to the storage in order to secure storage space in the main memory for performing the LLM and then moves data related to the LLM (e.g., Weight, key-value (KV) cache, etc.) from the storage to the main memory. For the user experience, the data-movement operation must be completed within a short time, and the speed at which the data-movement operation is performed may depend on the bandwidth between devices constituting the computing system of the mobile device. For example, data related to the LLM may be sequentially transferred through a NAND memory, a NAND controller, an application processor, and the main memory, but the bandwidth between the NAND controller and the application processor may be insufficient to perform fast data movement. In contrast, the bandwidth between the application processor and the main memory is much higher than the bandwidth between the NAND controller and the application processor. When the AI operation due to the execution of the LLM application is terminated, the application processor may move the data related to the existing applications, which were executed before the LLM application was executed, back from the NAND memory to the main memory. However, the insufficient bandwidth between the NAND controller and the application processor may become a bottleneck in performing fast data movement between the NAND memory and the main memory.

### SUMMARY

In an embodiment, a computing system may include a host, a main memory, and a storage apparatus. The storage apparatus may include a storage memory. The host may perform data communication with the main memory and the storage apparatus, respectively, in a first operation mode, and may directly move data between the main memory and the storage memory in a second operation mode.

In an embodiment, a computing system may include a host, a main memory, a storage memory, and a storage controller. The main memory may be coupled to the host through a first memory bus. The storage controller may be coupled to the host through a universal storage bus, may be coupled to the main memory through a second memory bus, and may be coupled to the storage memory through a storage bus.

In an embodiment, a computing system may include a host, a main memory, a storage memory, and a storage controller. The storage controller may be coupled to the host, the main memory, and the storage memory. The main memory may include a first memory chip configured to include a first pseudo channel and a second pseudo channel. Pads of the first pseudo channel may be coupled to the host, and pads of the second pseudo channel may be coupled to the storage controller.

In an embodiment, a computing system may include a host, a main memory, a storage controller, and a storage memory. The main memory may be coupled to the host through a first memory bus. The storage controller may be coupled to the host through a universal storage bus and may be coupled to the main memory through a second memory bus. The storage memory may be coupled to the storage controller through a storage bus. The main memory may be configured to transmit and receive data through the first memory bus in a first operation mode, and may be configured to transmit and receive data through the second memory bus in a second operation mode.

### BRIEF DESCRIPTION OF THE DRAWINGS

FIG. 1 is a diagram illustrating a configuration of a computing system according to an embodiment of the present disclosure.

FIG. 2 is a diagram illustrating a configuration of a computing system according to an embodiment of the present disclosure.

FIG. 3 is a diagram illustrating a configuration of a main memory and a connection relationship between the main memory and a host according to an embodiment of the present disclosure.

FIGS. 4A to 4C are diagrams illustrating a configuration of a main memory and a connection relationship between a host and the main memory and between a storage controller and the main memory according to an embodiment of the present disclosure.

FIGS. 5A and 5B are diagrams illustrating a configuration of a main memory according to an embodiment of the present disclosure.

FIG. 6 is a diagram illustrating a configuration of a computing system according to an embodiment of the present disclosure.

FIG. 7A is a diagram illustrating a configuration of a multi-chip package according to an embodiment of the present disclosure.

FIG. 7B is a diagram illustrating a configuration of a multi-chip package according to an embodiment of the present disclosure.

FIG. 8 is a diagram illustrating a configuration of a computing system according to an embodiment of the present disclosure.

FIG. 9 is a diagram illustrating a configuration of a computing system according to an embodiment of the present disclosure.

FIGS. 10A and 10B are diagrams illustrating configurations of computing systems, respectively, according to an embodiment of the present disclosure.

### DETAILED DESCRIPTION

In the following description of embodiments, terms such as “first” and “second” are used to distinguish between various elements and do not imply size, order, priority, quantity, or importance of the elements. For example, a first element may be named as a second element in one example, and the second element may be named as a first element in another example.

When one component is identified as “coupled” to another component, the components may be coupled directly or through an intervening component between the components. When two components are identified as “directly coupled,” one component is directly coupled to the other component without an intervening component between the two components.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

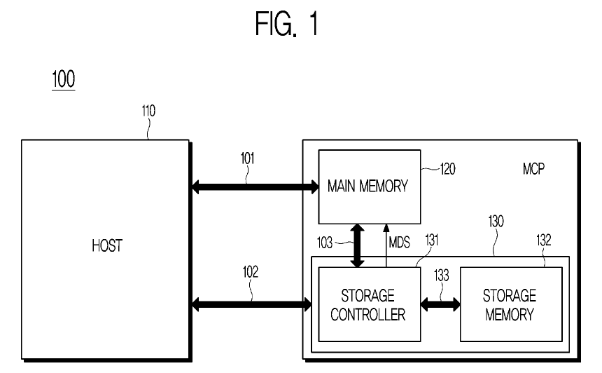

FIG. 1 is a diagram illustrating a configuration of a computing system 100 according to an embodiment of the present disclosure. Referring to FIG. 1, the computing system 100 may include a host 110, a main memory 120, and a storage apparatus 130. The host 110 may perform various computations in response to a user request and may be a master apparatus that accesses the main memory 120 and the storage apparatus 130 to perform various computations. The host 110 may provide various control signals to the main memory 120 and the storage apparatus 130 to communicate with the main memory 120 and the storage apparatus 130, respectively. The host 110 may include various types of processors. The main memory 120 may be controlled by the host 110 and may perform data communication with the host 110. The main memory 120 may include a volatile memory apparatus. For example, the main memory 120 may be any one of a double data rate random access memory (DDR RAM), a low-power double data rate random access memory (LPDDR RAM), and a graphics double data rate random access memory (GDDR RAM). The main memory 120 may include at least one memory chip. The storage apparatus 130 may be controlled by the host 110 and may perform data communication with the host 110. The storage apparatus 130 may include a storage controller 131 and a storage memory 132. The storage memory 132 may include a non-volatile memory apparatus that may function as a storage-class memory. For example, the storage memory 132 may include a flash memory, a phase change random access memory (PRAM), a magnetic random access memory (MRAM), a resistive random access memory (RRAM), and a ferroelectric random access memory (FRAM).

The host 110 may be coupled to the main memory 120 through a first memory bus 101. The host 110 may communicate with the main memory 120 through the first memory bus 101. The host 110 may access the main memory 120 through the first memory bus 101, transmit data to the main memory 120 through the first memory bus 101, and receive data transmitted from the main memory 120 through the first memory bus 101. An operation in which the host 110 transmits data to the main memory 120 may be a memory write operation, and an operation in which the main memory 120 transmits data to the host 110 may be a memory read operation. The host 110 may provide a first memory command address signal to the main memory 120 through the first memory bus 101 to access the main memory 120. The main memory 120 may receive the first memory command address signal transmitted from the host 110 through the first memory bus 101 and, based on the first memory command address signal, may transmit and receive data through the first memory bus 101. During the memory write operation, the main memory 120 may receive data transmitted from the host 110 through the first memory bus 101 and may store the received data. During the memory read operation, the main memory 120 may read data stored in the main memory 120 and may transmit the read data to the host 110 through the first memory bus 101.

The host 110 may be coupled to the storage apparatus 130 through a universal storage bus 102. For example, the universal storage bus 102 may be a Universal Flash Storage (UFS) bus. The host 110 may communicate with the storage apparatus 130 through the universal storage bus 102. The host 110 may access the storage apparatus 130 through the universal storage bus 102, transmit data to the storage apparatus 130 through the universal storage bus 102, and receive data transmitted from the storage apparatus 130 through the universal storage bus 102. An operation in which the host 110 transmits data to the storage apparatus 130 may be a storage write operation, and an operation in which the storage apparatus 130 transmits data to the host 110 may be a storage read operation. The storage controller 131 may be coupled to the storage memory 132 through a storage bus 133. The storage controller 131 may relay data communication between the host 110 and the storage memory 132. The storage controller 131 may receive a first command address signal from the universal storage bus 102 and may generate a storage command address signal based on the first command address signal. The storage controller 131 may provide the storage command address signal to the storage memory 132 through the storage bus 133. The storage memory 132 may transmit and receive data through the storage bus 133 based on the storage command address signal. During the storage write operation, the storage controller 131 may transmit data transmitted from the host 110 through the universal storage bus 102 to the storage memory 132 through the storage bus 133, and the storage memory 132 may store the data received through the storage bus 133. During the storage read operation, the storage memory 132 may read data stored in the storage memory 132 and may transmit the read data through the storage bus 133. The storage controller 131 may transmit the data received through the storage bus 133 to the host 110 through the universal storage bus 102.

The storage apparatus 130 may be further coupled to the main memory 120 through a second memory bus 103. The storage apparatus 130 may communicate with the main memory 120 through the second memory bus 103. The storage apparatus 130 may access the main memory 120 through the second memory bus 103, transmit data to the main memory 120 through the second memory bus 103, and receive data transmitted from the main memory 120 through the second memory bus 103. An operation in which data is transmitted from the storage apparatus 130 to the main memory 120 may be a direct swap write operation, and an operation in which data is transmitted from the main memory 120 to the storage apparatus 130 may be a direct swap read operation. The storage controller 131 may be coupled to the main memory 120 through the second memory bus 103. The storage controller 131 may receive a second command address signal from the host 110 through the universal storage bus 102 and may generate a second memory command address signal based on the second command address signal. The storage controller 131 may provide the second memory command address signal to the main memory 120. The main memory 120 may transmit and receive data through the second memory bus 103 based on the second memory command address signal transmitted through the second memory bus 103. During the direct swap write operation, the main memory 120 may receive data transmitted from the storage controller 131 through the second memory bus 103 and may store the received data. During the direct swap read operation, the main memory 120 may read data stored in the main memory 120 and may transmit the read data to the storage controller 131 through the second memory bus 103.

The main memory 120 and the storage apparatus 130 may be packaged as a single package, and the single package may be a multi-chip package (MCP). The first memory bus 101 and the universal storage bus 102 may be implemented through main board wirings. The second memory bus 103 and the storage bus 133 may be implemented through package board wirings. In an embodiment, the main memory 120 may be packaged as a package independent of the storage apparatus 130. In an embodiment, the storage bus 133 may be implemented through package board wirings, and the second memory bus 103 may be implemented through main board wirings.

The computing system 100 may operate in a first operation mode and a second operation mode. The host 110 may generate a mode command signal capable of setting one of the first and second operation modes. The host 110 may provide the mode command signal to the storage controller 131 through the universal storage bus 102, and the storage controller 131 may generate a mode signal MDS based on the mode command signal. The storage controller 131 may provide the mode signal MDS to the main memory 120. The storage controller 131 may transmit the mode signal MDS to the main memory 120 through the second memory bus 103 or may transmit the mode signal MDS to the main memory 120 through a separate wiring. The first operation mode may be a normal mode, and the second operation mode may be a direct swap mode. The normal mode may indicate a mode that is not the direct swap mode. The computing system 100 may operate as follows in the first and second operation modes.

### A. First Operation Mode (Normal Mode)

During the first operation mode, the host 110 may independently access the main memory 120 and the storage apparatus 130. The host 110 may, sequentially or in parallel, access the main memory 120 and the storage apparatus 130. The host 110 may perform data communication with the main memory 120 and may perform data communication with the storage apparatus 130. The host 110 may provide the first memory command address signal to the main memory 120 through the first memory bus 101 and may perform the memory write operation and the memory read operation with the main memory 120. The main memory 120 may receive data transmitted from the host 110 or may transmit data to the host 110 based on the first memory command address signal transmitted through the first memory bus 101. The host 110 may provide the first command address signal to the storage apparatus 130 through the universal storage bus 102 and may perform the storage write operation and the storage read operation with the storage apparatus 130. The host 110 may provide the first command address signal to the storage controller 131 through the universal storage bus 102, and the storage controller 131 may generate the storage command address signal based on the first command address signal. The storage controller 131 may provide the storage command address signal to the storage memory 132, and the storage memory 132 may receive data transmitted from the storage controller 131 or may transmit data to the storage controller 131 based on the storage command address signal. During the storage write operation, the storage controller 131 may provide data transmitted from the host 110 through the universal storage bus 102 to the storage memory 132 through the storage bus 133. During the storage read operation, the storage controller 131 may receive data transmitted from the storage memory 132 through the storage bus 133 and may transmit the received data to the host 110 through the universal storage bus 102. During the first operation mode, the storage controller 131 might not access the main memory 120.

### B. Second Operation Mode (Direct Swap Mode)

During the second operation mode, data may be directly moved between the storage apparatus 130 and the main memory 120. When the direct swap write operation is performed, the host 110 may provide the first command address signal to the storage controller 131. The storage controller 131 may generate the storage command address signal based on the first command address signal and may provide the storage command address signal to the storage memory 132. The storage memory 132 may read data stored in the storage memory 132 based on the storage command address signal and may transmit the read data to the storage controller 131 through the storage bus 133. The host 110 may provide the second command address signal to the storage controller 131. The storage controller 131 may generate the second memory command address signal based on the second command address signal and may provide the second memory command address signal to the main memory 120 through the second memory bus 103. The storage controller 131 may provide data transmitted from the storage memory 132 through the storage bus 133 to the main memory 120 through the second memory bus 103. The main memory 120 may store data transmitted from the storage controller 131 based on the second memory command address signal.

When the direct swap read operation is performed, the host 110 may provide the second command address signal to the storage controller 131. The storage controller 131 may generate the second memory command address signal based on the second command address signal and may provide the second memory command address signal to the main memory 120 through the second memory bus 103. The main memory 120 may read data stored in the main memory 120 based on the second memory command address signal and may transmit the read data to the storage controller 131 through the second memory bus 103. The host 110 may provide the first command address signal to the storage controller 131. The storage controller 131 may generate the storage command address signal based on the first command address signal and may provide the storage command address signal to the storage memory 132. The storage controller 131 may provide data transmitted from the main memory 120 through the second memory bus 103 to the storage memory 132 through the storage bus 133. The storage memory 132 may store data transmitted from the storage controller 131 based on the storage command address signal.

Because the computing system 100 includes the second memory bus 103 that connects the storage controller 131 to the main memory 120, during the second operation mode, a command address signal is provided from the host 110 to the storage apparatus 130, but data movement between the storage memory 132 and the main memory 120 may be directly performed without involvement of the host 110. A conventional computing system does not include the second memory bus 103, and involvement of the host 110 is required to move data between the storage memory 132 and the main memory 120. For example, in the conventional computing system, data transmitted from the storage memory 132 is transmitted to the host 110 through the storage controller 131 and the universal storage bus 102, and thereafter, the host 110 may provide the data transmitted from the storage memory 132 to the main memory 120 through the first memory bus 101. Conversely, the host 110 may receive data transmitted from the main memory 120 through the first memory bus 101, and thereafter, the host 110 may provide the data received from the main memory 120 to the storage controller 131 and the storage memory 132 through the universal storage bus 102. Because a bandwidth of the universal storage bus 102 is much smaller than a bandwidth of the first memory bus 101, data movement between the host 110 and the main memory 120 may be performed at a high speed, whereas data movement between the host 110 and the storage controller 131 may inevitably be performed at a low speed. A method of increasing the bandwidth of the universal storage bus 102 by increasing the number of transmission lines included in the universal storage bus 102 may be considered, but it may cause adverse effects, such as significant power consumption and heat generation. According to an embodiment of the present disclosure, the computing system 100 may improve a data movement speed between the storage memory 132 and the main memory 120 by allowing data movement between the storage memory 132 and the main memory 120 to be directly performed without passing through the host 110 during the second operation mode. In addition, the computing system 100 may reduce additional power consumption and heat generation by reducing an operation count and/or frequency of the universal storage bus 102.

In an embodiment, the computing system 100 may further support a third operation mode. The host 110 may generate the mode command signal capable of setting one of the first to third operation modes. The third operation mode may be a double bandwidth mode. The computing system 100 may operate as follows in the third operation mode.

### C. Third Operation Mode (Double Bandwidth Mode)

In the third operation mode, the main memory 120 may perform data communication respectively with the host 110 and the storage controller 131. Because the main memory 120 may perform the data communication with the storage controller 131 in parallel with performing the data communication with the host 110, the bandwidth of the computing system 100 may be doubled. In the third operation mode, the host 110 may perform the normal operation with the main memory 120, and the storage controller 131 may perform the direct swap operation with the main memory 120. The host 110 may provide the first memory command address signal to the main memory 120 and may perform the memory write operation and the memory read operation with the main memory 120. The main memory 120 may receive data transmitted from the host 110 or may transmit data to the host 110 based on the first memory command address signal transmitted from the host 110 through the first memory bus 101. The host 110 may provide the first and second command address signals to the storage controller 131 through the universal storage bus 102, and the storage controller 131 may perform the direct swap write operation and the direct swap read operation with the main memory 120. During the direct swap write operation, the storage controller 131 may generate the storage command address signal based on the first command address signal and may read data stored in the storage memory 132. The storage controller 131 may generate the second memory command address signal based on the second command address signal and may provide data read from the storage memory 132 to the main memory 120, and the main memory 120 may store data transmitted from the storage controller 131 in the main memory 120. During the direct swap read operation, the storage controller 131 may generate the second memory command address signal based on the second command address signal and may read data stored in the main memory 120. The storage controller 131 may generate the storage command address signal based on the first command address signal and may provide data read from the main memory 120 to the storage memory 132, and the storage memory 132 may store data transmitted from the storage controller 131 in the storage memory 132.

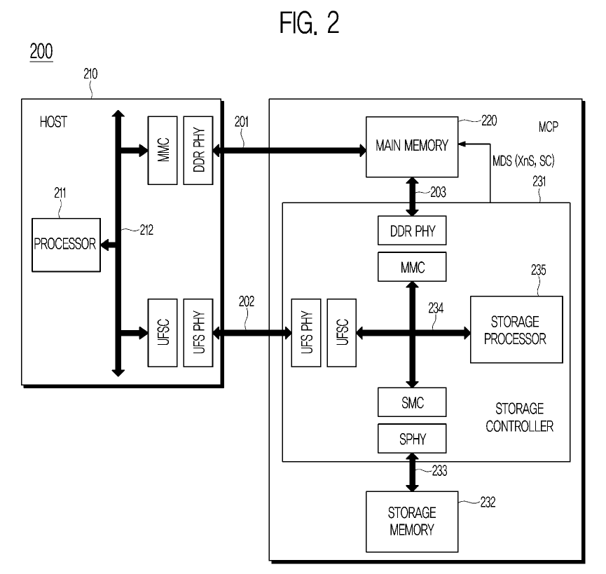

FIG. 2 is a diagram illustrating a configuration of a computing system 200 according to an embodiment of the present disclosure. Referring to FIG. 2, the computing system 200 may include a host 210, a main memory 220, a storage controller 231, and a storage memory 232. The host 210, the main memory 220, the storage controller 231, and the storage memory 232 may be substantially identical to the host 110, the main memory 120, the storage controller 131, and the storage memory 132 illustrated in FIG. 1, respectively. A duplicate description for identical components will be omitted. The host 210 may include a processor 211, a main memory controller MMC, and a universal storage controller UFSC. The processor 211 may perform one or more computations according to a user input and may control signal processing in the computing system 200. The processor 211 may control the main memory 220 and the storage memory 232 to perform various operations for performing the computations and may perform data communication with the main memory 220 and the storage memory 232. For example, the processor 211 may include one or more combinations of a central processing unit (CPU), a graphic processing unit (GPU), a neural processing unit (NPU), and an application processor (AP). The processor 211 may be coupled to the main memory controller MMC and the universal storage controller UFSC through an internal bus 212. The internal bus 212 may be a network-on-chip (NOC). The processor 211 may provide a request, a virtual address, data, etc. to the main memory controller MMC through the internal bus 212 to communicate with the main memory 220. The processor 211 may provide a request, a virtual address, data, etc. to the universal storage controller UFSC through the internal bus 212 to communicate with the storage memory 232.

The main memory controller MMC may be coupled to the main memory 220 through a first memory bus 201. The processor 211 may communicate with the main memory 220 through the main memory controller MMC. The main memory controller MMC may receive the request, the virtual address, and the data from the processor 211 through the internal bus 212 and may convert the request, the virtual address, and the data into signals suitable for use in the main memory 220. The main memory controller MMC may convert the virtual address into a physical address and may generate the first memory command address signal based on the request and the physical address. The main memory controller MMC may change a form of data received from the processor 211. For example, the main memory controller MMC may convert parallel data received from the processor 211 into serial data. The main memory controller MMC may provide the first memory command address signal to the main memory 220 through the first memory bus 201 and may provide the data received from the processor 211 to the main memory 220 through the first memory bus 201. The main memory controller MMC may also receive data transmitted from the main memory 220 through the first memory bus 201 and may provide the received data to the processor 211 through the internal bus 212. The host 210 may further include a memory interface circuit DDR PHY that transmits the first memory command address signal and the data generated from the main memory controller MMC and receives data transmitted from the main memory 220. The memory interface circuit DDR PHY may be a DDR physical layer. The memory interface circuit DDR PHY may include transmission circuits that transmit the first memory command address signal and the data through the first memory bus 201 and may include receiving circuits that receive data transmitted from the main memory 220 through the first memory bus 201. In an embodiment, the memory interface circuit DDR PHY may be integrated with the main memory controller MMC.

The universal storage controller UFSC may be coupled to the storage controller 231 through a universal storage bus 202. The processor 211 may communicate with the storage controller 231 and the storage memory 232 through the universal storage controller UFSC. The universal storage controller UFSC may receive the request, the virtual address, and the data from the processor 211 through the internal bus 212 and may convert the request, the virtual address, and the data into signals having a form suitable for being transmitted through the universal storage bus 202. The universal storage controller UFSC may generate the first command address signal and the second command address signal based on the request and the virtual address. The universal storage controller UFSC may also support various requests to be efficiently processed by performing command queuing. The universal storage controller UFSC may provide the first command address signal and the second command address signal to the storage controller 231 through the universal storage bus 202 and may provide the data received from the processor 211 to the storage controller 231 through the universal storage bus 202. The universal storage controller UFSC may also receive data transmitted from the storage controller 231 through the universal storage bus 202 and may provide the received data to the processor 211 through the internal bus 212. The host 210 may further include a universal interface circuit UFS PHY that transmits the first command address signal, the second command address signal, and the data generated from the universal storage controller UFSC and receives data transmitted from the storage controller 231. The universal interface circuit UFS PHY may be a universal flash storage physical layer. The universal interface circuit UFS PHY may include transmission circuits that transmit the first command address signal, the second command address signal, and the data through the universal storage bus 202 and may include receiving circuits that receive data transmitted from the storage controller 231 through the universal storage bus 202. In an embodiment, the universal interface circuit UFS PHY may be integrated with the universal storage controller UFSC.

The storage controller 231 may include a universal storage controller UFSC, a storage memory controller SMC, and a main memory controller MMC. The universal storage controller UFSC, the storage memory controller SMC, and the main memory controller MMC may be coupled to each other within through an internal bus 234 of the storage controller 231. The universal storage controller UFSC of the storage controller 231 may be coupled to the universal storage controller UFSC of the host 210 through the universal storage bus 202. The universal storage controller UFSC of the storage controller 231 may convert signals transmitted from the host 210 through the universal storage bus 202 into signals suitable for being transmitted through the internal bus 234. The storage controller 231 may further include a universal interface circuit UFS PHY. The universal interface circuit UFS PHY may include receiving circuits that receive the first command signal, the second command signal, and the data transmitted through the universal storage bus 202 and may include transmission circuits that transmit data from the storage controller 231 to the host 210. In an embodiment, the universal interface circuit UFS PHY may be integrated with the universal storage controller UFSC.

The storage memory controller SMC may be coupled to the storage memory 232 through a storage memory bus 233. The storage memory controller SMC may communicate with the storage memory 232 through the storage memory bus 233. The storage memory controller SMC may receive the first command address signal from the universal storage controller UFSC and may generate the storage command address signal from the first command address signal and may provide the storage command address signal to the storage memory 232. The storage memory controller SMC may receive the data transmitted from the universal storage controller UFSC through the internal bus 234 and may provide the received data to the storage memory 232. The storage memory controller SMC may receive the data transmitted from the storage memory 232 through the storage memory bus 233 and may provide the received data to the universal storage controller UFSC through the internal bus 234. The storage controller 231 may further include a storage interface circuit SPHY. The storage interface circuit SPHY may be a storage memory physical layer. The storage interface circuit SPHY may include transmission circuits that transmit the storage command address signal and the data to the storage memory 232 through the storage memory bus 233 and may include receiving circuits that receive the data transmitted from the storage memory 232. In an embodiment, the storage interface circuit SPHY may be integrated with the storage memory controller SMC.

The main memory controller MMC may be coupled to the main memory 220 through a second memory bus 203. The main memory controller MMC may communicate with the main memory 220 through the second memory bus 203. The main memory controller MMC may receive the second command address signal from the universal storage controller UFSC through the internal bus 234 and may generate the second memory command address signal from the second command address signal and may provide the second memory command address signal to the main memory 220 through the second memory bus 203. The main memory controller MMC may receive the data transmitted from the storage memory controller SMC through the internal bus 234 and may provide the received data to the main memory 220 through the second memory bus 203. The main memory controller MMC may receive the data transmitted from the main memory 220 through the second memory bus 203 and may transmit the received data through the internal bus 234. The storage controller 231 may further include a memory interface circuit DDR PHY. The memory interface circuit DDR PHY may include transmission circuits that transmit the second memory command address signal and the data to the main memory 220 through the second memory bus 203 and may include receiving circuits that receive the data transmitted from the main memory 220. In an embodiment, the memory interface circuit DDR PHY may be integrated with the main memory controller MMC.

The storage controller 231 may further include a storage processor 235. The storage processor 235 may control communication between the universal storage controller UFSC and the storage memory controller SMC and may control communication between the universal storage controller UFSC and the main memory controller MMC. The storage processor 235 may perform various functions. For example, the storage processor 235 may map a logical address transmitted from the host 210 to a physical address of the storage memory 232, perform wear leveling of the storage memory 232, and perform error correction for the data transmitted through the storage memory bus 233. In addition, the storage processor 235 may manage bad blocks of the storage memory 232 and may mitigate read disturbance effects. In addition, the storage processor 235 may put a plurality of commands transmitted from the host 210 into a queue and may schedule the plurality of commands according to priority to determine a processing order of the plurality of commands.

The processor 211 may generate the mode command signal to change between the first and second operation modes, and the universal storage controller UFSC may transmit the mode command signal to the storage controller 231 through the universal storage bus 202. The storage controller 231 may generate the mode signal MDS based on the mode command signal. The mode signal MDS may include an input/output mode signal XnS and a channel selection signal SC. The mode signal MDS will be described later. The universal storage controller UFSC of the storage controller 231 may provide the mode command signal to the main memory controller MMC, and the main memory controller MMC may generate the mode signal MDS from the mode command signal. The main memory controller MMC may provide the mode signal MDS to the main memory 220 through the memory interface circuit DDR PHY. In an embodiment, the storage processor 235 may receive the mode command signal, generate the mode signal MDS based on the mode command signal, and provide the mode signal MDS to the main memory 220. In this case, the storage processor 235 may provide the mode signal MDS to the main memory 220 using a separate transmission circuit instead of the memory interface circuit DDR PHY.

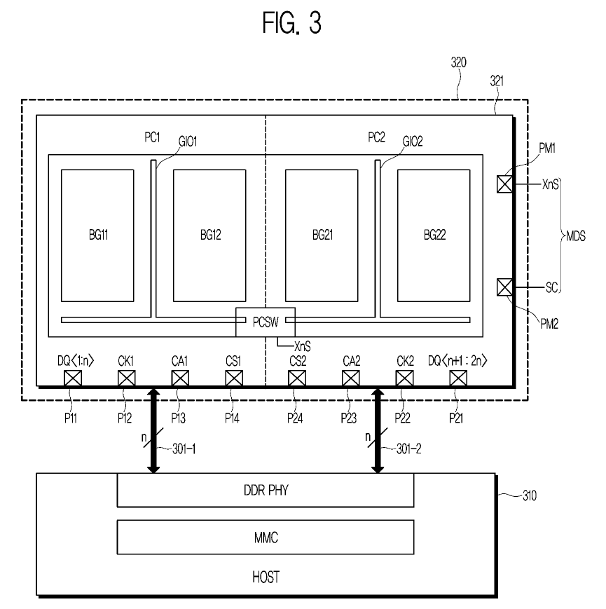

FIG. 3 is a diagram illustrating a configuration of a main memory 320 and a connection relationship between the main memory 320 and a host 310 according to an embodiment of the present disclosure. The main memory 320 may include a memory chip 321. The memory chip 321 may include a plurality of memory banks capable of storing data. For example, the memory chip 321 may include a first bank group BG11, a second bank group BG12, a third bank group BG21, and a fourth bank group BG22. The first to fourth bank groups BG11, BG12, BG21, and BG22 may each include a plurality of memory banks and may include an identical number of memory banks. The memory chip 321 may include a first pseudo channel PC1 and a second pseudo channel PC2. The pseudo channel may be a unit configuration capable of independently performing data input/output operations. The memory chip 321 may perform a data input/output operation by activating one or both of the first and second pseudo channels PC1 and PC2. The first pseudo channel PC1 may include the first bank group BG11 and the second bank group BG12 and may include first data pads P11, first clock pads P12, first command address pads P13, and a first chip selection pad P14. Memory banks included in the first bank group BG11 and the second bank group BG12 may be referred to as memory banks of the first pseudo channel PC1. The first data pads P11, the first clock pads P12, the first command address pads P13, and the first chip selection pad P14 may each be referred to as pads of the first pseudo channel PC1. The second pseudo channel PC2 may include the third bank group BG21 and the fourth bank group BG22 and may include second data pads P21, second clock pads P22, second command address pads P23, and a second chip selection pad P24. Memory banks included in the third bank group BG21 and the fourth bank group BG22 may be referred to as memory banks of the second pseudo channel PC2. The second data pads P21, the second clock pads P22, the second command address pads P23, and the second chip selection pad P24 may each be referred to as pads of the second pseudo channel PC2. The first data pads P11 are coupled to a first data bus 301-1, and the second data pads P21 may be coupled to a second data bus 301-2. The number of first data pads P11 and the number of transmission lines included in the first data bus 301-1 may be n. The number of second data pads P21 and the number of transmission lines included in the second data bus 301-2 may be n. Here, n may be an integer greater than or equal to 4. The first and second bank groups BG11 and BG12 may be coupled to a first global I/O line GIO1. The first data pads P11 are coupled to the first data bus 301-1 and may transmit and receive first data signals DQ<1:n> through the first data bus 301-1. The third and fourth bank groups BG21 and BG22 may be coupled to a second global I/O line GIO2. The second data pads P21 are coupled to the second data bus 301-2 and may transmit and receive second data signals DQ<n+1:2n> through the second data bus 301-2. The first clock pads P12 receive a first clock signal CK1, the first command address pads P13 receive a first command address signal CA1 of the first pseudo channel, and the first chip selection pad P14 receives a first chip selection signal CS1. The second clock pads P22 receive a second clock signal CK2, the second command address pads P23 receive a second command address signal CA2 of the second pseudo channel, and the second chip selection pad P24 receives a second chip selection signal CS2. The memory chip 321 may further include a pseudo-channel switching circuit PCSW. The pseudo-channel switching circuit PCSW may selectively couple the first global I/O lines GIO1 to the second global I/O line GIO2. The pseudo-channel switching circuit PCSW will be described later.

The host 310 may be coupled to the memory chip 321 through the first and second data buses 301-1 and 301-2. The first and second data buses 301-1 and 301-2 may be portions of the first memory buses 101 and 201 illustrated in FIGS. 1 and 2. Transmission lines of the memory bus that transmit the first and second clock signals CK1 and CK2, command address signals CA1 and CA2 of the first and second pseudo channels, and the first and second chip selection signals CS1 and CS2 are not separately illustrated in FIG. 3. The host 310 may include a main memory controller MMC and a memory interface circuit DDR PHY. The main memory controller MMC may provide the first data signals DQ<1:n>, the first clock signal CK1, the command address signal CA1 of the first pseudo channel, the first chip selection signal CS1, the second data signals DQ<n+1:2n>, the second clock signal CK2, the command address signal CA2 of the second pseudo channel, and the second chip selection signal CS2 to the memory chip 321 through the memory interface circuit DDR PHY. The main memory controller MMC may receive the first data signals DQ<1:n> and the second data signals DQ<n+1:2n> transmitted from the memory chip 321 through the memory interface circuit DDR PHY.

The memory chip 321 may support a first data input/output mode and a second data input/output mode by including two pseudo channels. The first data input/output mode may be a one-channel mode in which a data input/output operation is performed through n transmission lines. The second data input/output mode may be a two-channel mode in which a data input/output operation is performed through 2n transmission lines. In the first data input/output mode, the host 310 may transmit data through the n transmission lines, and the memory chip 321 may also transmit data through the n transmission lines. In the first data input/output mode, one of the first and second pseudo channels PC1 and PC2 may be selected. For example, when the first pseudo channel PC1 is selected, a data input/output operation may be performed through pads of the first pseudo channel PC1, and data may be transmitted through the first data bus 301-1. The pseudo-channel switching circuit PCSW may couple the first global I/O line to the second global I/O line GIO2. The host 310 may provide the first clock signal CK1, the command address signal CA1 of the first pseudo channel, and the first chip selection signal CS1 to access the first to fourth bank groups BG11, BG12, BG21, and BG22. During the memory write operation, the first data signals DQ<1:n> transmitted from the host 310 may be received through the first data pads P11. Based on the command address signal CA1 of the first pseudo channel, the first data signals DQ<1:n> may be provided to the first and second bank groups BG11 and BG12 through the first global I/O line GIO1 and may be stored in the first and second bank groups BG11 and BG12, or the first data signals DQ<1:n> may be provided to the third and fourth bank groups BG21 and BG22 through the second global I/O line GIO2 and may be stored in the third and fourth bank groups BG21 and BG22. During the memory read operation, based on the command address signal CA1 of the first pseudo channel, data read from the first and second bank groups BG11 and BG12 may be provided to the first data pads P11 through the first global I/O line GIO1, or data read from the third and fourth bank groups BG21 and BG22 may be provided to the first data pads P11 through the second global I/O line GIO2. The first data signals DQ<1:n> may be provided to the host 310 through the first data pads P11 and the first data bus 301-1. Conversely, when the second pseudo channel PC2 is selected, a data input/output operation may be performed through pads of the second pseudo channel PC2, and data may be transmitted through the second data bus 301-2. The pseudo-channel switching circuit PCSW may couple the first global I/O lines GIO1 to the second global I/O line GIO2. The host 310 may provide the second clock signal CK2, the command address signal CA2 of the second pseudo channel, and the second chip selection signal CS2 to access the first to fourth bank groups BG11, BG12, BG21, and BG22.

During the memory write operation, the second data signals DQ<n+1:2n> transmitted from the host 310 may be received through the second data pads P21. Based on the command address signal CA2 of the second pseudo channel, the second data signals DQ<n+1:2n> may be provided to the first and second bank groups BG11 and BG12 through the first global I/O line GIO1 and may be stored in the first and second bank groups BG11 and BG12, or the second data signals DQ<n+1:2n> may be provided to the third and fourth bank groups BG21 and BG22 through the second global I/O line GIO2 and may be stored in the third and fourth bank groups BG21 and BG22. During the memory read operation, based on the command address signal CA2 of the second pseudo channel, data read from the first and second bank groups BG11 and BG12 may be provided to the second data pads P21 through the first global I/O line GIO1, or data read from the third and fourth bank groups BG21 and BG22 may be provided to the second data pads P21 through the second global I/O line GIO2. The second data signals DQ<n+1:2n> may be provided to the host 310 through the second data pads P21 and the second data bus 301-2.

During the second data input/output mode, the host 310 may transmit data through the 2n transmission lines, and the memory chip 321 may also transmit data through the 2n transmission lines. In the second data input/output mode, both the first and second pseudo channels PC1 and PC2 may be selected, and the first and second pseudo channels PC1 and PC2 may independently perform data input/output operations. The host 310 may provide the first clock signal CK1, the command address signal CA1 of the first pseudo channel, and the first chip selection signal CS1 to perform a data input/output operation with the first pseudo channel PC1 and may provide the second clock signal CK2, the command address signal CA2 of the second pseudo channel, and the second chip selection signal CS2 to perform a data input/output operation with the second pseudo channel PC2. The pseudo-channel switching circuit PCSW may separate the first and second global I/O lines GIO1 and GIO2. The host 310 may access the first and second bank groups BG11 and BG12 through pads of the first pseudo channel PC1 and may access the third and fourth bank groups BG21 and BG22 through pads of the second pseudo channel PC2. During the memory write operation, the first data signals DQ<1:n> transmitted from the host 310 through the first data bus 301-1 may be provided to the first and second bank groups BG11 and BG12 through the first data pads P11 and the first global I/O line GIO1 and may be stored in the first and second bank groups BG11 and BG12. The second data signals DQ<n+1:2n> transmitted from the host 310 through the second data bus 301-2 may be provided to the third and fourth bank groups BG21 and BG22 through the second data pads P21 and the second global I/O line GIO2 and may be stored in the third and fourth bank groups BG21 and BG22. During the memory read operation, data read from the first and second bank groups BG11 and BG12 may be provided to the first data pads P11 through the first global I/O line GIO1, and the first data signals DQ<1:n> may be provided to the host 310 through the first data pads P11 and the first data bus 301-1. Data read from the third and fourth bank groups BG21 and BG22 may be provided to the second data pads P21 through the second global I/O line GIO2, and the second data signals DQ<n+1:2n> may be provided to the host 310 through the second data pads P21 and the second data bus 301-2.

The main memory 320 may set the data input/output mode based on a mode signal MDS. The mode signal MDS may include an input/output mode signal XnS and a channel selection signal SC. The memory chip 321 may receive the input/output mode signal XnS through a pad PM1 and may receive the channel selection signal SC through a pad PM2. When the input/output mode signal XnS is at a logic high level, a data input/output mode of the memory chip 321 may be set to the first data input/output mode. When the channel selection signal SC is at a logic low level, the first pseudo channel PC1 may be selected, and the memory chip 321 may perform the data input/output operation through pads of the first pseudo channel PC1. When the channel selection signal SC is at a logic high level, the second pseudo channel PC2 may be selected, and the memory chip 321 may perform the data input/output operation through pads of the second pseudo channel PC2. When the input/output mode signal XnS is at a logic low level, a data input/output mode of the memory chip 321 may be set to the second data input/output mode. Regardless of a logic level of the channel selection signal SC, both the first and second pseudo channels PC1 and PC2 may be selected, and both the first and second pseudo channels PC1 and PC2 may perform the data input/output operation. The pseudo-channel switching circuit PCSW may receive the input/output mode signal XnS. When the input/output mode signal XnS is at a logic high level, the pseudo-channel switching circuit PCSW may couple the first global I/O line GIO1 to the second global I/O line GIO2. When the input/output mode signal XnS is at a logic low level, the pseudo-channel switching circuit PCSW may separate the first global I/O lines GIO1 from the second global I/O line GIO2.

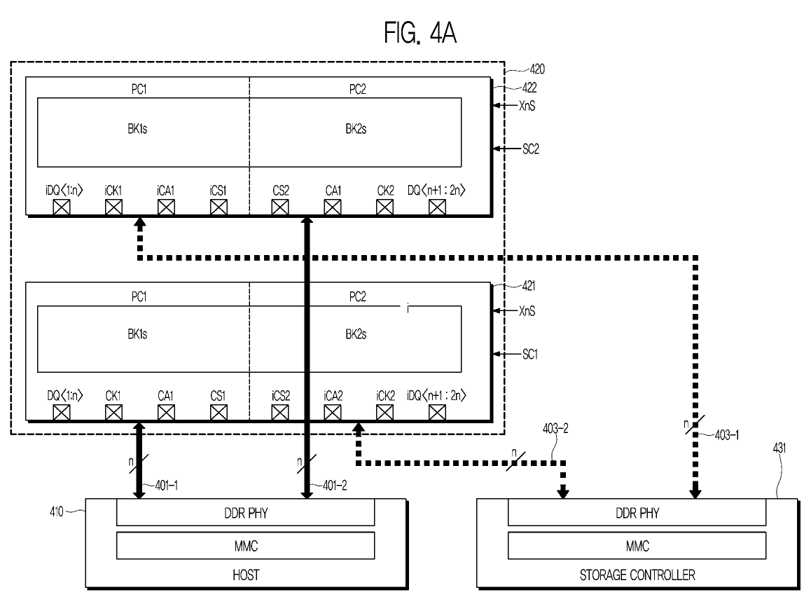

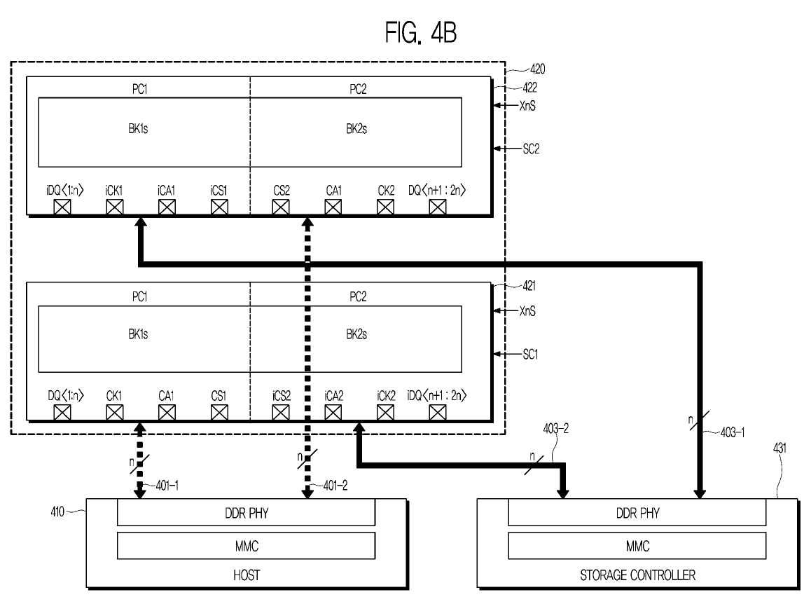

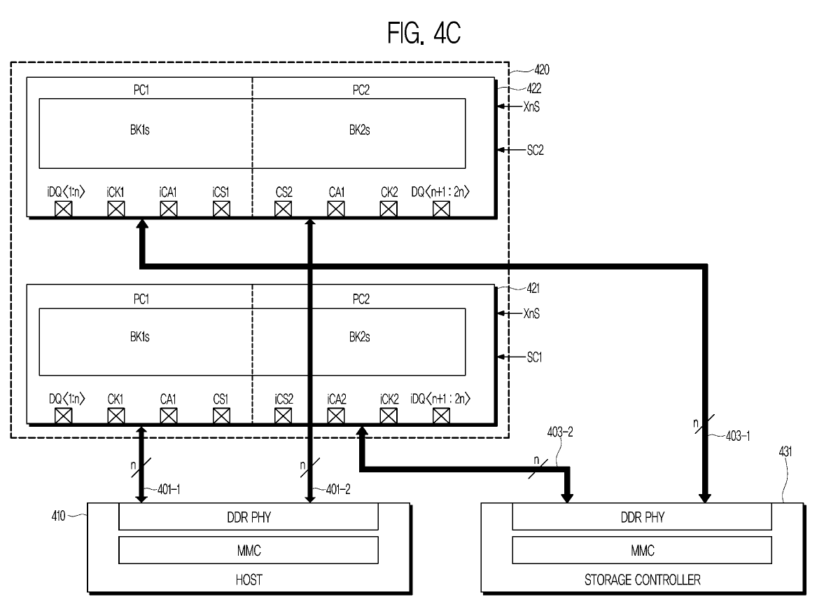

FIGS. 4A to 4C are diagrams illustrating a configuration of a main memory 420 and a connection relationship between a host 410 and the main memory 420 and between a storage controller 431 and the main memory 420 according to an embodiment of the present disclosure. Referring to FIGS. 4A to 4C, the main memory 420 may include a first memory chip 421 and a second memory chip 422. In FIGS. 4A to 4C, it is illustrated that the main memory 420 includes two memory chips, but this is not intended to limit the number of memory chips included in the main memory 420. The main memory 420 may include memory chips, the number of which is a multiple of two. Each of the first and second memory chips 421 and 422 may be substantially identical in configuration to the memory chip 321 illustrated in FIG. 3. A first pseudo channel PC1 of the first memory chip 421 may be coupled to the host 410 through a first data bus 401-1 of the first memory bus. A second pseudo channel PC2 of the first memory chip 421 may be coupled to the storage controller 431 through a second data bus 403-2 of the second memory bus. A first pseudo channel PC1 of the second memory chip 422 may be coupled to the storage controller 431 through a first data bus 403-1 of the second memory bus. A second pseudo channel PC2 of the second memory chip 422 may be coupled to the host 410 through a second data bus 401-2 of the first memory bus. In FIGS. 4A to 4C, to distinguish signals received from or transmitted to the host 410 from signals received from or transmitted to the storage controller 431, a prefix “i” is additionally attached in front of signals received from or transmitted to the storage controller 431.

The first memory chip 421 may receive, as the mode signal, the input/output mode signal XnS and a first channel selection signal SC1. The second memory chip 422 may receive, as the mode signal, the input/output mode signal XnS and a second channel selection signal SC2. During the first operation mode, the host 410 may transmit the mode command signal, and the storage controller 431 may generate the input/output mode signal XnS having a logic high level, the first channel selection signal SC1 having a logic low level, and the second channel selection signal SC2 having a logic high level. As illustrated in FIG. 4A, based on the input/output mode signal XnS and the first channel selection signal SC1, the first pseudo channel PC1 of the first memory chip 421 may be selected, and the second pseudo channel PC2 might not be selected. While a connection between pads of the first pseudo channel PC1 in the first memory chip 421 and the host 410 is activated, a connection between the first memory chip 421 and the storage controller 431 may be deactivated. Based on the input/output mode signal XnS and the second channel selection signal SC2, the second pseudo channel PC2 of the second memory chip 422 may be selected, and the first pseudo channel PC1 might not be selected. While a connection between pads of the second pseudo channel PC2 of the second memory chip 422 and the host 410 is activated, a connection between the second memory chip 422 and the storage controller 431 may be deactivated. The host 410 may access both memory banks BK1s of the first pseudo channel PC1 in the first memory chip 421 and memory banks BK2s of the second pseudo channel PC2 in the first memory chip 421 through pads of the first pseudo channel PC1 in the first memory chip 421. The host 410 may also access both memory banks BK1s of the first pseudo channel PC1 in the second memory chip 422 and memory banks BK2s of the second pseudo channel PC2 in the second memory chip 422 through pads of the second pseudo channel PC2 in the second memory chip 422. Because the host 410 is respectively coupled to the pads of the first pseudo channel PC1 in the first memory chip 421 and the pads of the second pseudo channel PC2 in the second memory chip 422, even when the first and second memory chips 421 and 422 operate in the first data input/output mode, the host 410 may operate in the second data input/output mode, and a bandwidth between the host 410 and the main memory 420 may be sufficiently secured. Through the main memory controller MMC, the memory interface circuit DDR PHY, and the first memory bus, the host 410 may provide the first clock signal CK1, a command address signal CA1 of the first pseudo channel, and the first chip selection signal CS1 to pads of the first pseudo channel PC1 in the first memory chip 421 and may also provide the second clock signal CK2, a command address signal CA2 of the second pseudo channel, and the second chip selection signal CS2 to pads of the second pseudo channel PC2 in the second memory chip 422. During the memory write operation, the host 410 may transmit the first data signals DQ<1:n> to the pads of the first pseudo channel PC1 in the first memory chip 421 through the first data bus 401-1 of the first memory bus and may transmit the second data signals DQ<n+1:2n> to the pads of the second pseudo channel PC2 in the second memory chip 422 through the second data bus 401-2 of the first memory bus. The first data signals DQ<1:n> may be stored in the memory banks BK1s and BK2s of the first and second pseudo channels PC1 and PC2 in the first memory chip 421, and the second data signals DQ<n+1:2n> may be stored in the memory banks BK1s and BK2s of the first and second pseudo channels PC1 and PC2 in the second memory chip 422. During the memory read operation, data read from the memory banks BK1s and BK2s of the first and second pseudo channels PC1 and PC2 in the first memory chip 421 may be transmitted to the host 410 as the first data signals DQ<1:n> through the first data bus 401-1, and data read from the memory banks BK1s and BK2s of the first and second pseudo channels PC1 and PC2 in the second memory chip 422 may be transmitted to the host 410 as the second data signals DQ<n+1:2n> through the second data bus 401-2.

To change the first operation mode to the second operation mode, the host 410 may transmit the mode command signal, and the storage controller 431 may, based on the mode command signal, generate the input/output mode signal XnS having a logic high level, the first channel selection signal SC1 having a logic high level, and the second channel selection signal SC2 having a logic low level. As illustrated in FIG. 4B, based on the input/output mode signal XnS and the first channel selection signal SC1, the second pseudo channel PC2 of the first memory chip 421 may be selected, and the first pseudo channel PC1 might not be selected. While a connection between pads of the second pseudo channel PC2 in the first memory chip 421 and the storage controller 431 is activated, a connection between the first memory chip 421 and the host 410 may be deactivated. Based on the input/output mode signal XnS and the second channel selection signal SC2, the first pseudo channel PC1 of the second memory chip 422 may be selected, and the second pseudo channel PC2 might not be selected. While a connection between pads of the first pseudo channel PC1 in the second memory chip 422 and the storage controller 431 is activated, a connection between the second memory chip 422 and the host 410 may be deactivated. The storage controller 431 may access the memory banks BK1s and BK2s of the first and second pseudo channels PC1 and PC2 in the first memory chip 421 through pads of the second pseudo channel PC2 in the first memory chip 421. The storage controller 431 may also access the memory banks BK1s and BK2s of the first and second pseudo channels PC1 and PC2 in the second memory chip 422 through pads of the first pseudo channel PC1 in the second memory chip 422. Because the storage controller 431 is respectively coupled to pads of the second pseudo channel PC2 in the first memory chip 421 and pads of the first pseudo channel PC1 in the second memory chip 422, even when the first and second memory chips 421 and 422 operate in the first data input/output mode, the storage controller 431 may operate in the second data input/output mode, and a bandwidth between the storage controller 431 and the main memory 420 may be sufficiently secured. Through the main memory controller MMC, the memory interface circuit DDR PHY, and the second memory bus, the storage controller 431 may provide the second clock signal iCK2, a command address signal iCA2 of the second pseudo channel, and the second chip selection signal iCS2 to pads of the second pseudo channel PC2 in the first memory chip 421 and may also provide the first clock signal iCK1, a command address signal iCA1 of the first pseudo channel, and the first chip selection signal iCS1 to pads of the first pseudo channel PC1 in the second memory chip 422. During the memory write operation, the storage controller 431 may transmit the first data signals iDQ<1:n> to pads of the first pseudo channel PC1 in the second memory chip 422 through the first data bus 403-1 of the second memory bus and may transmit the second data signals iDQ<n+1:2n> to pads of the second pseudo channel PC2 in the first memory chip 421 through the second data bus 403-2 of the second memory bus. The first data signals iDQ<1:n> may be stored in the memory banks BK1s and BK2s of the first and second pseudo channels PC1 and PC2 in the second memory chip 422, and the second data signals iDQ<n+1:2n> may be stored in the memory banks BK1s and BK2s of the first and second pseudo channels PC1 and PC2 in the first memory chip 421. During the memory read operation, data read from the memory banks BK1s and BK2s of the first and second pseudo channels PC1 and PC2 in the second memory chip 422 may be transmitted to the storage controller 431 as the first data signals iDQ<1:n> through the first data bus 403-1, and data read from the memory banks BK1s and BK2s of the first and second pseudo channels PC1 and PC2 in the first memory chip 421 may be transmitted to the storage controller 431 as the second data signals iDQ<n+1:2n> through the second data bus 403-2.

To change the first operation mode or the second operation mode to the third operation mode, the host 410 may transmit the mode command signal, and the storage controller 431 may generate the input/output mode signal XnS having a logic low level based on the mode command signal. As illustrated in FIG. 4C, based on the input/output mode signal XnS, the first and second pseudo channels PC1 and PC2 of the first memory chip 421 may both be selected. Connections between pads of the first pseudo channel PC1 in the first memory chip 421 and the host 410 and between pads of the second pseudo channel PC2 in the first memory chip 421 and the storage controller 431 may both be activated. Based on the input/output mode signal XnS, the first and second pseudo channels PC1 and PC2 of the second memory chip 422 may both be selected. Connections between pads of the first pseudo channel PC1 in the second memory chip 422 and the storage controller 431 and between pads of the second pseudo channel PC2 in the second memory chip 422 and the host 410 may both be activated. The host 410 may access the memory banks BK1s of the first pseudo channel PC1 in the first memory chip 421 through pads of the first pseudo channel PC1 in the first memory chip 421 and may access the memory banks BK2s of the second pseudo channel PC2 in the second memory chip 422 through pads of the second pseudo channel PC2 in the second memory chip 422. Through the main memory controller MMC, the memory interface circuit DDR PHY, and the first memory bus, the host 410 may provide the first clock signal CK1, the command address signal CA1 of the first pseudo channel, and the first chip selection signal CS1 to pads of the first pseudo channel PC1 in the first memory chip 421 and may provide the second clock signal CK2, the command address signal CA2 of the second pseudo channel, and the second chip selection signal CS2 to pads of the second pseudo channel PC2 in the second memory chip 422. During the memory write operation, the host 410 may transmit the first data signals DQ<1:n> to pads of the first pseudo channel PC1 in the first memory chip 421 through the first data bus 401-1 of the first memory bus and may transmit the second data signals DQ<n+1:2n> to pads of the second pseudo channel PC2 in the second memory chip 422 through the second data bus 401-2 of the first memory bus. The first data signals DQ<1:n> may be stored in the memory banks BK1s of the first pseudo channel PC1 in the first memory chip 421, and the second data signals DQ<n+1:2n> may be stored in the memory banks BK2s of the second pseudo channel PC2 in the second memory chip 422. During the memory read operation, data read from the memory banks BK1s of the first pseudo channel PC1 in the first memory chip 421 may be transmitted to the host 410 as the first data signals DQ<1:n> through the first data bus 401-1. Data read from the memory banks BK2s of the second pseudo channel PC2 in the second memory chip 422 may be transmitted to the host 410 as the second data signals DQ<n+1:2n> through the second data bus 401-2. The storage controller 431 may access the memory banks BK2s of the second pseudo channel PC2 in the first memory chip 421 through pads of the second pseudo channel PC2 in the first memory chip 421 and may access the memory banks BK1s of the first pseudo channel PC1 in the second memory chip 422 through pads of the first pseudo channel PC1 in the second memory chip 422. Through the main memory controller MMC, the memory interface circuit DDR PHY, and the second memory bus, the storage controller 431 may provide the second clock signal iCK2, the command address signal iCA2 of the second pseudo channel, and the second chip selection signal iCS2 to pads of the second pseudo channel PC2 in the first memory chip 421 and may provide the first clock signal iCK1, the command address signal iCA1 of the first pseudo channel, and the first chip selection signal iCS1 to pads of the first pseudo channel PC1 in the second memory chip 422. During the direct swap write operation, the storage controller 431 may transmit the first data signals iDQ<1:n> to pads of the first pseudo channel PC1 in the second memory chip 422 through the first data bus 403-1 of the second memory bus and may transmit the second data signals iDQ<n+1:2n> to pads of the second pseudo channel PC2 in the first memory chip 421 through the second data bus 403-2 of the second memory bus. The first data signals iDQ<1:n> may be stored in the memory banks BK1s of the first pseudo channel PC1 in the second memory chip 422, and the second data signals iDQ<n+1:2n> may be stored in the memory banks BK2s of the second pseudo channel PC2 in the first memory chip 421. During the direct swap read operation, data read from the memory banks BK1s of the first pseudo channel PC1 in the second memory chip 422 may be transmitted to the storage controller 431 as the first data signals iDQ<1:n> through the first data bus 403-1, and data read from the memory banks BK2s of the second pseudo channel PC2 in the first memory chip 421 may be transmitted to the storage controller 431 as the second data signals iDQ<n+1:2n> through the second data bus 403-2. While the data signals DQ<1:2n> transmitted between the host 410 and the main memory 420 may be stored in the memory banks BK1s of the first pseudo channel PC1 in the first memory chip 421 and the memory banks BK2s of the second pseudo channel PC2 in the second memory chip 422, the data signals iDQ<1:2n> transmitted between the storage controller 431 and the main memory 420 may be stored in the memory banks BK2s of the second pseudo channel PC2 in the first memory chip 421 and the memory banks BK1s of the first pseudo channel PC1 in the second memory chip 422. Accordingly, data communication between the host 410 and the main memory 420 and data communication between the storage controller 431 and the main memory 420 may be independently performed.

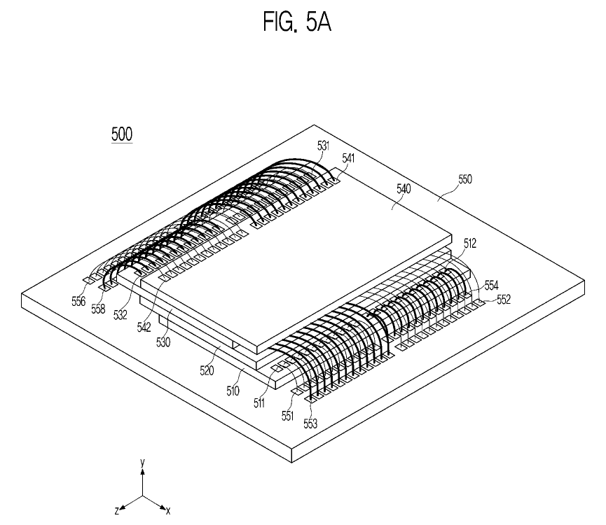

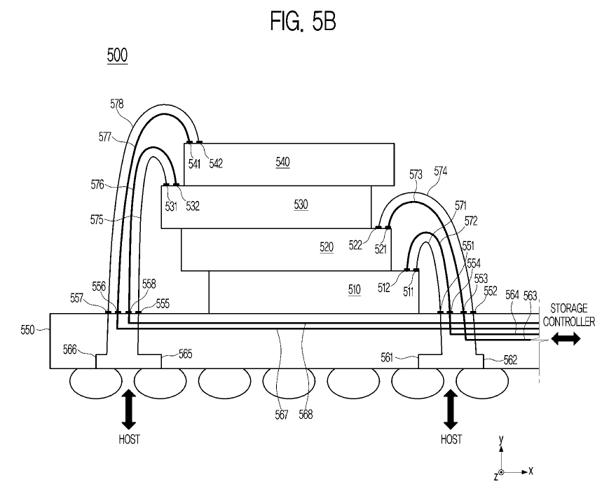

FIGS. 5A and 5B are diagrams illustrating a configuration of a main memory 500 according to an embodiment of the present disclosure. FIG. 5A is a perspective view of the main memory 500, and FIG. 5B is a vertical cross-sectional view of the main memory 500. Referring to FIGS. 5A and 5B, the main memory 500 may include a first memory chip 510, a second memory chip 520, a third memory chip 530, and a fourth memory chip 540. The first to fourth memory chips 510, 520, 530, and 540 may be stacked on a package substrate 550. The package substrate 550 may be a multi-chip package substrate or may be a memory package substrate. The first memory chip 510 may be disposed on the package substrate 550 in a y-axis direction, the second memory chip 520 may be disposed on the first memory chip 510 in the y-axis direction, the third memory chip 530 may be disposed on the second memory chip 520 in the y-axis direction, and the fourth memory chip 540 may be disposed on the third memory chip 530 in the y-axis direction. DAF (Die Attached Film) may be provided between the package substrate 550 and the first memory chip 510, between the first and second memory chips 510 and 520, between the second and third memory chips 520 and 530, and between the third and fourth memory chips 530 and 540. The first to fourth memory chips 510, 520, 530, and 540 may include pads 511 and 512, 521 and 522, 531 and 532, and 541 and 542, respectively, on one side thereof. The first and second memory chips 510 and 520 may be disposed such that the pads 511, 512, 521, and 522 of the first and second memory chips 510 and 520 are exposed on a first side of each of the first and second memory chips 510 and 520, respectively, and the pads 511 and 512 are spaced apart from the pads 521 and 522, respectively, in the x-axis direction. The third and fourth memory chips 530 and 540 may be disposed such that the pads 531, 532, 541, and 542 of the third and fourth memory chips 530 and 540 are exposed on a second side of each of the third and fourth memory chips 530 and 540, respectively, and the pads 531 and 532 are spaced apart from the pads 541 and 542, respectively, in the x-axis direction. The second side may be an area that is on the opposite side of the first side. The second memory chip 520 may be disposed in a stepped manner on the first memory chip 510 such that the pads 511 and 512 of the first memory chip 510 are exposed along the first side of the first memory chip 510. The second memory chip 520 may be disposed on the first memory chip 510 while being shifted in a (-x) direction (i.e., shifted to the left in FIG. 5B). The third memory chip 530 may be disposed in a stepped manner on the second memory chip 520 such that the pads 521 and 522 of the second memory chip 520 are exposed along the first side of the second memory chip 520. The third memory chip 530 may be disposed on the second memory chip 520 while being shifted in the (-x) direction. The fourth memory chip 540 may be disposed in a stepped manner on the third memory chip 530 such that the pads 531 and 532 of the third memory chip 530 are exposed along the second side of the third memory chip 530. The fourth memory chip 540 may be disposed on the third memory chip 530 while being shifted in a (+x) direction (i.e., shifted to the right in FIG. 5B).

First pads 551, second pads 552, third pads 553, and fourth pads 554 may be formed on the package substrate 550 to be adjacent to the first side of the first to fourth memory chips 510, 520, 530, and 540. Fifth pads 555, sixth pads 556, seventh pads 557, and eighth pads 558 may be formed on the package substrate 550 to be adjacent to the second side of the first to fourth memory chips 510, 520, 530, and 540. The first pads 551 may be coupled to the host through a wiring 561 of the package substrate 550 and the first memory bus. The first pads 551 may be coupled to a first data bus of the first memory bus. The second pads 552 may be coupled to the host through a wiring 562 of the package substrate 550 and the first memory bus, and the second pads 552 may be coupled to a second data bus of the first memory bus. The third pads 553 may be coupled to the storage controller through a wiring 563 of the package substrate 550 and the second memory bus, and the third pads 553 may be coupled to a first data bus of the second memory bus. The fourth pads 554 may be coupled to the storage controller through a wiring 564 of the package substrate 550 and the second memory bus, and the fourth pads 554 may be coupled to a second data bus of the second memory bus. The fifth pads 555 may be coupled to the host through a wiring 565 of the package substrate 550 and the first memory bus, and the fifth pads 555 may be coupled to a third data bus of the first memory bus. The sixth pads 556 may be coupled to the host through a wiring 566 of the package substrate 550 and the first memory bus, and the sixth pads 556 may be coupled to a fourth data bus of the first memory bus. The seventh pads 557 may be coupled to the storage controller through a wiring 567 of the package substrate 550 and the second memory bus, and the seventh pads 557 may be coupled to a third data bus of the second memory bus. The eighth pads 558 may be coupled to the storage controller through a wiring 568 of the package substrate 550 and the second memory bus, and the eighth pads 558 may be coupled to a fourth data bus of the second memory bus.

The pads of the first memory chip 510 may include the pads 511 of a first pseudo channel and the pads 512 of a second pseudo channel, the pads of the second memory chip 520 may include the pads 521 of a first pseudo channel and the pads 522 of a second pseudo channel, the pads of the third memory chip 530 may include the pads 531 of a first pseudo channel and the pads 532 of a second pseudo channel, and the pads of the fourth memory chip 540 may include the pads 541 of a first pseudo channel and the pads 542 of a second pseudo channel. The pads 511 of the first pseudo channel in the first memory chip 510 may be coupled to the first pads 551. The pads 511 of the first pseudo channel in the first memory chip 510 may be coupled to the first pads 551 through first bonding wires 571. The pads 512 of the second pseudo channel in the first memory chip 510 may be coupled to the fourth pads 554. The pads 512 of the second pseudo channel in the first memory chip 510 may be coupled to the fourth pads 554 through second bonding wires 572. The pads 521 of the first pseudo channel in the second memory chip 520 may be coupled to the third pads 553. The pads 521 of the first pseudo channel in the second memory chip 520 may be coupled to the third pads 553 through third bonding wires 573. The pads 522 of the second pseudo channel in the second memory chip 520 may be coupled to the second pads 552. The pads 522 of the second pseudo channel in the second memory chip 520 may be coupled to the second pads 552 through fourth bonding wires 574. The pads 531 of the first pseudo channel in the third memory chip 530 may be coupled to the fifth pads 555. The pads 531 of the first pseudo channel in the third memory chip 530 may be coupled to the fifth pads 555 through fifth bonding wires 575. The pads 532 of the second pseudo channel in the third memory chip 530 may be coupled to the eighth pads 558. The pads 532 of the second pseudo channel in the third memory chip 530 may be coupled to the eighth pads 558 through sixth bonding wires 576. The pads 541 of the first pseudo channel in the fourth memory chip 540 may be coupled to the seventh pads 557. The pads 541 of the first pseudo channel in the fourth memory chip 540 may be coupled to the seventh pads 557 through seventh bonding wires 577. The pads 542 of the second pseudo channel in the fourth memory chip 540 may be coupled to the sixth pads 556. The pads 542 of the second pseudo channel in the fourth memory chip 540 may be coupled to the sixth pads 556 through eighth bonding wires 578. The pads 511 of the first pseudo channel in the first memory chip 510 and the pads 522 of the second pseudo channel in the second memory chip 520 may be coupled to the first memory bus and the host respectively through the first pads 551 and the second pads 552. The pads 531 of the first pseudo channel in the third memory chip 530 and the pads 542 of the second pseudo channel in the fourth memory chip 540 may be coupled to the first memory bus and the host respectively through the fifth pads 555 and the sixth pads 556. In contrast, the pads 512 of the second pseudo channel in the first memory chip 510 and the pads 521 of the first pseudo channel in the second memory chip 520 may be coupled to the second memory bus and the storage controller respectively through the fourth pads 554 and the third pads 553. The pads 532 of the second pseudo channel in the third memory chip 530 and the pads 541 of the first pseudo channel in the fourth memory chip 540 may be coupled to the second memory bus and the storage controller respectively through the eighth pads 558 and the seventh pads 557.

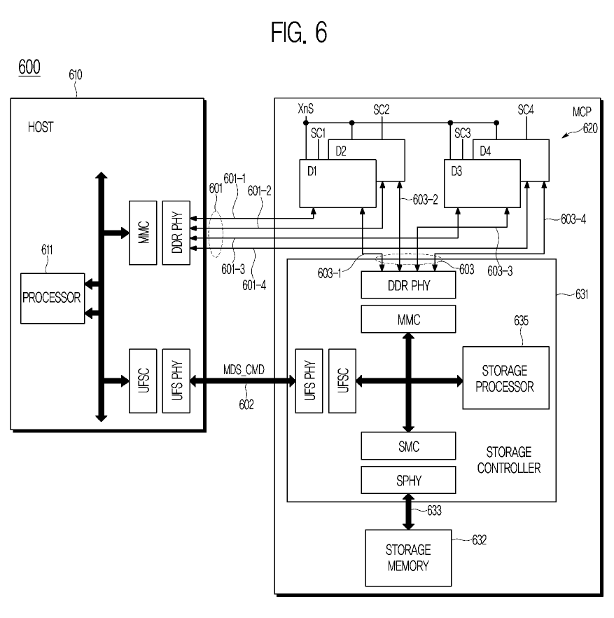

FIG. 6 is a diagram illustrating a configuration of a computing system 600 according to an embodiment of the present disclosure. The computing system 600 has a configuration substantially identical to the computing system 200 illustrated in FIG. 2, and a configuration of a main memory 620 is illustrated in more detail in FIG. 6. A redundant description for the same components will be omitted. The main memory 620 may include a first memory chip D1, a second memory chip D2, a third memory chip D3, and a fourth memory chip D4. The first to fourth memory chips D1, D2, D3, and D4 may be stacked on top of each other as illustrated for the first to fourth memory chips 510, 520, 530, and 540 in FIGS. 5A and 5B. The first memory chip D1 may receive the input/output mode signal XnS and a first channel selection signal SC1, the second memory chip D2 may receive the input/output mode signal XnS and a second channel selection signal SC2, the third memory chip D3 may receive the input/output mode signal XnS and a third channel selection signal SC3, and the fourth memory chip D4 may receive the input/output mode signal XnS and a fourth channel selection signal SC4.

During the first operation mode, the input/output mode signal XnS may be at a logic high level, the first and third channel selection signals SC1 and SC3 may be at a logic low level, and the second and fourth channel selection signals SC2 and SC4 may be at a logic high level. A first pseudo channel of the first memory chip D1 may be selected, and a second pseudo channel of the first memory chip D1 might not be selected. Pads of the first pseudo channel in the first memory chip D1 may be coupled to the memory interface circuit DDR PHY of the host 610 and the main memory controller MMC through the first memory bus 601 and the first data bus 601-1. A second pseudo channel of the second memory chip D2 may be selected, and a first pseudo channel of the second memory chip D2 might not be selected. Pads of the second pseudo channel in the second memory chip D2 may be coupled to the memory interface circuit DDR PHY of the host 610 and the main memory controller MMC through the first memory bus 601 and a second data bus 601-2. A first pseudo channel of the third memory chip D3 may be selected, and a second pseudo channel of the third memory chip D3 might not be selected. Pads of the first pseudo channel in the third memory chip D3 may be coupled to the memory interface circuit DDR PHY of the host 610 and the main memory controller MMC through the first memory bus 601 and a third data bus 601-3. A second pseudo channel of the fourth memory chip D4 may be selected, and a first pseudo channel of the fourth memory chip D4 might not be selected. Pads of the second pseudo channel in the fourth memory chip D4 may be coupled to the memory interface circuit DDR PHY of the host 610 and the main memory controller MMC through the first memory bus 601 and a fourth data bus 601-4. When the memory write operation is performed, the main memory controller MMC may provide the first memory command address signal to the first to fourth memory chips D1, D2, D3, and D4 through the first memory bus 601 and may transmit data signals through the first to fourth data buses 601-1, 601-2, 601-3, and 601-4. Pads of the first pseudo channel in the first memory chip D1 may receive data transmitted through the first data bus 601-1, and the first memory chip D1 may store the received data in memory banks of the first and second pseudo channels. Pads of the second pseudo channel in the second memory chip D2 may receive data transmitted through the second data bus 601-2, and the second memory chip D2 may store the received data in memory banks of the first and second pseudo channels. Pads of the first pseudo channel in the third memory chip D3 may receive data transmitted through the third data bus 601-3, and the third memory chip D3 may store the received data in memory banks of the first and second pseudo channels. Pads of the second pseudo channel in the fourth memory chip D4 may receive data transmitted through the fourth data bus 601-4, and the fourth memory chip D4 may store the received data in memory banks of the first and second pseudo channels. When the memory read operation is performed, the main memory controller MMC may provide the first memory command address signal to the first to fourth memory chips D1, D2, D3, and D4. The first memory chip D1 may read data stored in memory banks of the first and second pseudo channels in the first memory chip D1 and may transmit the read data to the main memory controller MMC through pads of the first pseudo channel in the first memory chip D1 and the first data bus 601-1. The second memory chip D2 may read data stored in memory banks of the first and second pseudo channels in the second memory chip D2 and may transmit the read data to the main memory controller MMC through pads of the second pseudo channel in the second memory chip D2 and the second data bus 601-2. The third memory chip D3 may read data stored in memory banks of the first and second pseudo channels in the third memory chip D3 and may transmit the read data to the main memory controller MMC through pads of the first pseudo channel in the third memory chip D3 and the third data bus 601-3. The fourth memory chip D4 may read data stored in memory banks of the first and second pseudo channels in the fourth memory chip D4 and may transmit the read data to the main memory controller MMC through pads of the second pseudo channel in the fourth memory chip D4 and the fourth data bus 601-4.

When the first operation mode is changed to the second operation mode, the processor 611 may transmit the mode command signal MDS_CMD to the storage controller 631 through the universal storage controller UFSC, the universal interface circuit UFS PHY, and the universal storage bus 602. Based on the mode command signal MDS_CMD, the storage controller 631 may change the first and third channel selection signals SC1 and SC3 from a logic low level to a logic high level and may change the second and fourth channel selection signals SC2 and SC4 from a logic high level to a logic low level. The second pseudo channel of the first memory chip D1 may be selected, and the first pseudo channel of the first memory chip D1 might not be selected. Pads of the second pseudo channel in the first memory chip D1 may be coupled to the memory interface circuit DDR PHY and the main memory controller MMC of the storage controller 631 through the second memory bus 603 and a first data bus 603-1. The first pseudo channel of the second memory chip D2 may be selected, and the second pseudo channel of the second memory chip D2 might not be selected. Pads of the first pseudo channel in the second memory chip D2 may be coupled to the memory interface circuit DDR PHY and the main memory controller MMC of the storage controller 631 through the second memory bus 603 and a second data bus 603-2. The second pseudo channel of the third memory chip D3 may be selected, and the first pseudo channel of the third memory chip D3 might not be selected. Pads of the second pseudo channel in the third memory chip D3 may be coupled to the memory interface circuit DDR PHY and the main memory controller MMC of the storage controller 631 through the second memory bus 603 and a third data bus 603-3. The first pseudo channel of the fourth memory chip D4 may be selected, and the second pseudo channel of the fourth memory chip D4 might not be selected. Pads of the first pseudo channel in the fourth memory chip D4 may be coupled to the memory interface circuit DDR PHY and the main memory controller MMC of the storage controller 631 through the second memory bus 603 and a fourth data bus 603-4.

When the direct swap write operation is performed, the processor 611 may transmit the first command address signal to the storage controller 631 through the universal storage controller UFSC and the universal storage bus 602. The storage memory controller SMC of the storage controller 631 may generate the storage command address signal based on the first command address signal and may provide the storage command address signal to the storage memory 632 through the storage bus 633. The storage memory 632 may output data stored in the storage memory 632 based on the storage command address signal. After transmitting the first command address signal, the processor 611 may transmit the second command address signal to the storage controller 631 through the universal storage controller UFSC and the universal storage bus 602. The main memory controller MMC of the storage controller 631 may generate the second memory command address signal based on the second command address signal and may provide the second memory command address signal to the first to fourth memory chips D1, D2, D3, and D4 through the second memory bus 603. Data output from the storage memory 632 may be transmitted to the first to fourth memory chips D1, D2, D3, and D4 through the storage memory controller SMC, the main memory controller MMC, and the first to fourth data buses 603-1, 603-2, 603-3, and 603-4. The pads of the second pseudo channel in the first memory chip D1 may receive data transmitted through the first data bus 603-1, and the first memory chip D1 may store the received data in memory banks of the first and second pseudo channels. The pads of the first pseudo channel in the second memory chip D2 may receive data transmitted through the second data bus 603-2, and the second memory chip D2 may store the received data in memory banks of the first and second pseudo channels. The pads of the second pseudo channel in the third memory chip D3 may receive data transmitted through the third data bus 603-3, and the third memory chip D3 may store the received data in memory banks of the first and second pseudo channels. The pads of the first pseudo channel in the fourth memory chip D4 may receive data transmitted through the fourth data bus 603-4, and the fourth memory chip D4 may store the received data in memory banks of the first and second pseudo channels.

When the direct swap read operation is performed, the processor 611 may transmit the second command address signal to the storage controller 631 through the universal storage controller UFSC and the universal storage bus 602. The main memory controller MMC of the storage controller 631 may generate the second memory command address signal based on the second command address signal and may provide the second memory command address signal to the first to fourth memory chips D1, D2, D3, and D4 through the second memory bus 603. The first memory chip D1 may read data stored in memory banks of the first and second pseudo channels and may transmit the read data to the storage controller 631 through pads of the second pseudo channel in the first memory chip D1 and the first data bus 603-1. The second memory chip D2 may read data stored in memory banks of the first and second pseudo channels and may transmit the read data to the storage controller 631 through pads of the first pseudo channel in the second memory chip D2 and the second data bus 603-2. The third memory chip D3 may read data stored in memory banks of the first and second pseudo channels and may transmit the read data to the storage controller 631 through pads of the second pseudo channel in the third memory chip D3 and the third data bus 603-3. The fourth memory chip D4 may read data stored in memory banks of the first and second pseudo channels and may transmit the read data to the storage controller 631 through pads of the first pseudo channel in the fourth memory chip D4 and the fourth data bus 603-4. After transmitting the second command address signal, the processor 611 may transmit the first command address signal to the storage controller 631 through the universal storage controller UFSC and the universal storage bus 602. The storage memory controller SMC of the storage controller 631 may generate the storage command address signal based on the first command address signal and may provide the storage command address signal to the storage memory 632 through the storage bus 633. Data output from the first to fourth memory chips D1, D2, D3, and D4 may be transmitted to the storage memory 632 through the main memory controller MMC, the storage memory controller SMC, and the storage bus 633. The storage memory 632 may store data transmitted through the storage bus 633.

The processor 611 may generate the mode command signal MDS_CMD capable of changing the input/output mode signal XnS to a logic low level to set the third operation mode and may provide the mode command signal MDS_CMD to the storage controller 631. The storage controller 631 may change the input/output mode signal XnS from a logic high level to a logic low level based on the mode command signal MDS_CMD. The first and second pseudo channels of the first to fourth memory chips D1, D2, D3, and D4 may all be selected. Pads of the first pseudo channel in the first memory chip D1 may be coupled to the main memory controller MMC of the host 610 through the first memory bus 601 and the first data bus 601-1, and pads of the second pseudo channel in the first memory chip D1 may be coupled to the main memory controller MMC of the storage controller 631 through the second memory bus 603 and the first data bus 603-1. Pads of the first pseudo channel in the second memory chip D2 may be coupled to the main memory controller MMC of the storage controller 631 through the second memory bus 603 and the second data bus 603-2, and pads of the second pseudo channel in the second memory chip D2 may be coupled to the main memory controller MMC of the host 610 through the first memory bus 601 and the second data bus 601-2. Pads of the first pseudo channel in the third memory chip D3 may be coupled to the main memory controller MMC of the host 610 through the first memory bus 601 and the third data bus 601-3, and pads of the second pseudo channel in the third memory chip D3 may be coupled to the main memory controller MMC of the storage controller 631 through the second memory bus 603 and the third data bus 603-3. Pads of the first pseudo channel in the fourth memory chip D4 may be coupled to the main memory controller MMC of the storage controller 631 through the second memory bus 603 and the fourth data bus 603-4, and pads of the second pseudo channel in the fourth memory chip D4 may be coupled to the main memory controller MMC of the host 610 through the first memory bus 601 and the fourth data bus 601-4.

The host 610 may provide the first memory command address signal through the first memory bus 601 to the pads of the first pseudo channels of the first and third memory chips D1 and D3 and to the pads of the second pseudo channels of the second and fourth memory chips D2 and D4. During the memory write operation, data transmitted from the host 610 may be stored in memory banks of the first pseudo channels of the first and third memory chips D1 and D3 and in memory banks of the second pseudo channels of the second and fourth memory chips D2 and D4. During the memory read operation, data may be read from the memory banks of the first pseudo channels of the first and third memory chips D1 and D3 and from the memory banks of the second pseudo channels of the second and fourth memory chips D2 and D4, and the read data may be transmitted to the host 610. In order to perform the direct swap write operation, the host 610 may transmit the first command address signal through the universal storage bus 602 and then may transmit the second command address signal. The storage controller 631 may generate the storage command address signal based on the first command address signal and may provide the storage command address signal to the storage memory 632. The storage controller 631 may generate the second memory command address signal based on the second command address signal and may provide the second memory command address signal through the second memory bus 603 to the pads of the second pseudo channels of the first and third memory chips D1 and D3 and to the pads of the first pseudo channels of the second and fourth memory chips D2 and D4. During the direct swap write operation, data output from the storage memory 632 may be stored in memory banks of the second pseudo channels of the first and third memory chips D1 and D3 and in memory banks of the first pseudo channels of the second and fourth memory chips D2 and D4. In order to perform the direct swap read operation, the host 610 may transmit the second command address signal through the universal storage bus 602 and then may transmit the first command address signal. The storage controller 631 may generate the second memory command address signal based on the second command address signal and may provide the second memory command address signal through the second memory bus 603 to the pads of the second pseudo channels of the first and third memory chips D1 and D3 and to the pads of the first pseudo channels of the second and fourth memory chips D2 and D4. The storage controller 631 may generate the storage command address signal based on the first command address signal and may provide the storage command address signal to the storage memory 632. During the direct swap read operation, data output from the memory banks of the second pseudo channels of the first and third memory chips D1 and D3 and from the memory banks of the first pseudo channels of the second and fourth memory chips D2 and D4 may be stored in the storage memory 632.

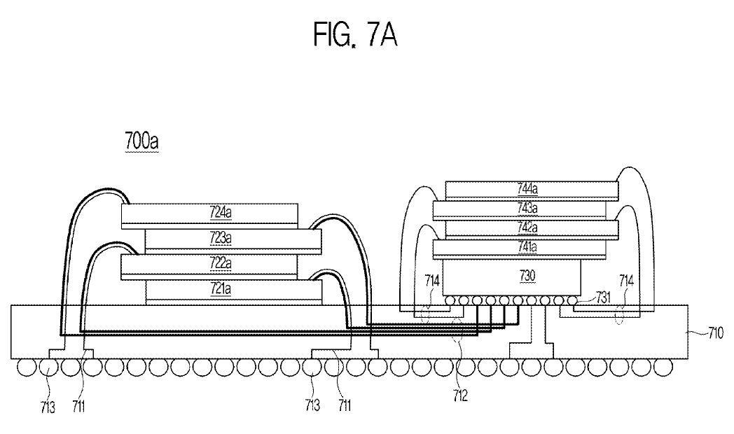

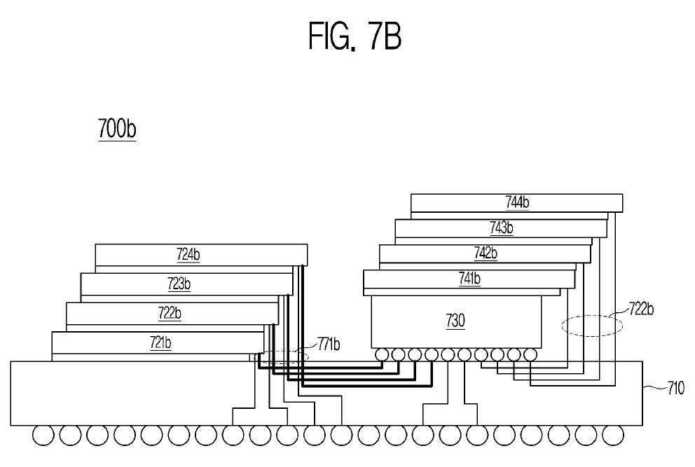

FIG. 7A is a diagram illustrating a configuration of a multi-chip package 700a according to an embodiment of the present disclosure. Referring to FIG. 7A, the multi-chip package 700a may include a package substrate 710, first to fourth memory chips 721a, 722a, 723a, and 724a, a storage controller 730, and first to fourth storage memory chips 741a, 742a, 743a, and 744a. The first to fourth memory chips 721a, 722a, 723a, and 724a may constitute a main memory, and the first to fourth storage memory chips 741a, 742a, 743a, and 744a may constitute a storage memory. Although the multi-chip package 700a is illustrated as including four storage memory chips, this is not intended to limit the number of storage memory chips included in the multi-chip package 700a. The multi-chip package 700a may include one, two, or four or more storage memory chips. The first to fourth memory chips 721a, 722a, 723a, and 724a may be disposed on a first region of the package substrate 710. The first to fourth memory chips 721a, 722a, 723a, and 724a may be disposed in an offset manner as described in FIGS. 5A and 5B. The storage controller 730 may be disposed on a second region of the package substrate 710. The second region might not overlap with the first region. The first to fourth storage memory chips 741a, 742a, 743a, and 744a may be sequentially disposed on the storage controller 730 in an offset manner. DAF may be provided between the storage controller 730 and the first storage memory chip 741a, between the first and second storage memory chips 741a and 742a, between the second and third storage memory chips 742a and 743a, and between the third and fourth storage memory chips 743a and 744a.

Pads of a first pseudo channel in the first memory chip 721a may be coupled to pads formed on the package substrate 710 through bonding wires and may be coupled to the host through wiring 711 of the package substrate 710 and package balls 713. Pads of a second pseudo channel in the first memory chip 721a may be coupled to pads formed on the package substrate 710 through bonding wires and may be coupled to the storage controller 730 through wiring 712 of the package substrate 710. Pads of a first pseudo channel in the second memory chip 722a may be coupled to pads formed on the package substrate 710 through bonding wires and may be coupled to the storage controller 730 through the wiring 712 of the package substrate 710. Pads of a second pseudo channel in the second memory chip 722a may be coupled to pads formed on the package substrate 710 through bonding wires and may be coupled to the host through the wiring 711 of the package substrate 710 and package balls 713. Pads of a first pseudo channel in the third memory chip 723a may be coupled to pads formed on the package substrate 710 through bonding wires and may be coupled to the host through the wiring 711 of the package substrate 710 and package balls 713. Pads of a second pseudo channel in the third memory chip 723a may be coupled to pads formed on the package substrate 710 through bonding wires and may be coupled to the storage controller 730 through the wiring 712 of the package substrate 710. Pads of a first pseudo channel in the fourth memory chip 724a may be coupled to pads formed on the package substrate 710 through bonding wires and may be coupled to the storage controller 730 through the wiring 712 of the package substrate 710. Pads of the second pseudo channel in the fourth memory chip 724a may be coupled to pads formed on the package substrate 710 through bonding wires and may be coupled to the host through the wiring 711 of the package substrate 710 and package balls 713. The storage controller 730 may be coupled to the first to fourth memory chips 721a, 722a, 723a, and 724a through bumps 731 and the wiring 712.

Pads of the first storage memory chip 741a may be coupled to pads formed on the package substrate 710 through bonding wires and may be coupled to the storage controller 730 through wiring 714 of the package substrate 710 and the bumps 731. Pads of the second storage memory chip 742a may be coupled to pads formed on the package substrate 710 through bonding wires and may be coupled to the storage controller 730 through the wiring 714 of the package substrate 710 and the bumps 731. Pads of the third storage memory chip 743a may be coupled to pads formed on the package substrate 710 through bonding wires and may be coupled to the storage controller 730 through the wiring 714 of the package substrate 710 and the bumps 731. Pads of the fourth storage memory chip 744a may be coupled to pads formed on the package substrate 710 through bonding wires and may be coupled to the storage controller 730 through the wiring 714 of the package substrate 710 and the bumps 731.

As the number of memory chips and storage memory chips mounted on the multi-chip package substrate increases, the number of bonding wires coupling the memory chips and the storage memory chips to pads of the package substrate 710 increases, and an increase in the number of bonding wires may increase a manufacturing difficulty of the multi-chip package. FIG. 7B is a diagram illustrating a configuration of a multi-chip package 700b according to an embodiment of the present disclosure. To facilitate manufacturing of the multi-chip package 700b, as illustrated in FIG. 7B, a vertical wire bonding technique may be used. Referring to FIG. 7B, the first to fourth memory chips 721b, 722b, 723b, and 724b may be flipped, shifted in one direction, and sequentially stacked in a stepped structure. Pads of the first to fourth memory chips 721b, 722b, 723b, and 724b may be coupled to pads formed on the package substrate 710 using vertical bonding wires 771b. The first to fourth storage memory chips 741b, 742b, 743b, and 744b may be flipped, shifted in one direction on the storage controller 730, and sequentially stacked in the stepped structure. Pads of the first to fourth storage memory chips 741b, 742b, 743b, and 744b may be coupled to pads formed on the package substrate 710 using vertical bonding wires 772b.

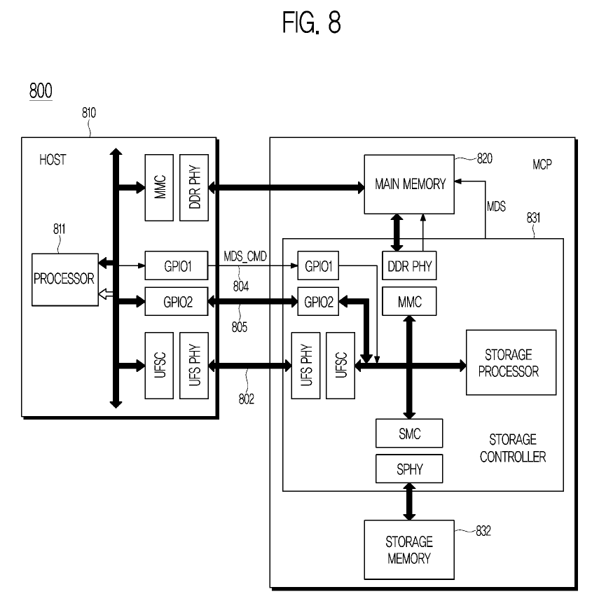

FIG. 8 is a diagram illustrating a configuration of a computing system 800 according to an embodiment of the present disclosure. The computing system 800 includes components that are substantially identical to those of the computing system 600 illustrated in FIG. 6, and redundant descriptions for identical components will be omitted. The host 810 may provide the mode command signal MDS_CMD to the storage controller 831 to change the first operation mode to the second operation mode. In addition, the host 810 may provide the second command address signal to the storage controller 831 to perform the direct swap write operation and the direct swap read operation during the second operation mode. However, because the universal storage bus 802 has long latency and small bandwidth, providing the mode command signal MDS_CMD and the second command address signal through the universal storage bus 802 may reduce a data movement speed performed between the main memory 820 and the storage memory 832. Therefore, a method of providing the mode command signal MDS_CMD and the second command address signal from the host 810 to the storage controller 831 through a separate bus having shorter latency than the universal storage bus 802 may be considered. The host 810 and the storage controller 831 may respectively include a plurality of general purpose input and output (GPIO) circuits. A first GPIO circuit GPIO1 of the host 810 may be coupled to a first GPIO circuit GPIO1 of the storage controller 831 through a first GPIO bus 804. A second GPIO circuit GPIO2 of the host 810 may be coupled to a second GPIO circuit GPIO2 of the storage controller 831 through a second GPIO bus 805. In an embodiment, the first and second GPIO circuits GPIO1 and GPIO2 of the host 810 may be integrated into a single GPIO circuit, and the first and second GPIO circuits GPIO1 and GPIO2 of the storage controller 831 may also be integrated into a single GPIO circuit, and the first and second GPIO buses 804 and 805 may be integrated into a single GPIO bus. The host 810 and the storage controller 831 may be coupled through the first and second GPIO buses 804 and 805 to transmit various types of custom signals, such as test signals and alarm signals, through user programming. The computing system 800 may increase a data movement speed performed between the main memory 820 and the storage memory 832 by respectively transmitting the mode command signal MDS_CMD and the second command address signal through the first and second GPIO buses 804 and 805. The first GPIO circuit GPIO1 of the host 810 may transmit the mode command signal MDS_CMD received from the processor 811 to the storage controller 831 through the first GPIO bus 804. The first GPIO circuit GPIO1 of the storage controller 831 may receive the mode command signal MDS_CMD transmitted from the host 810 and may generate the mode signal MDS based on the mode command signal MDS_CMD. The second GPIO circuit GPIO2 of the host 810 may transmit the second command address signal received from the processor 811 to the storage controller 831 through the second GPIO bus 805. The second GPIO circuit GPIO2 of the storage controller 831 may receive the second command address signal transmitted from the host 810 and may provide the second command address signal to the main memory controller MMC of the storage controller 831.

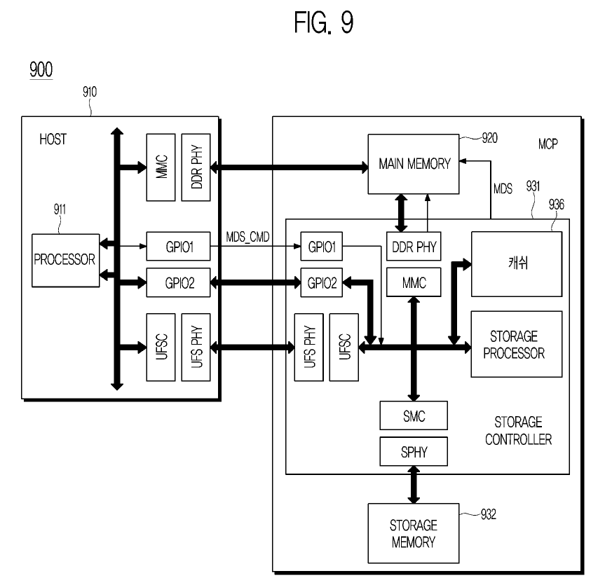

FIG. 9 is a diagram illustrating a configuration of a computing system 900 according to an embodiment of the present disclosure. The computing system 900 includes components that are substantially identical to those of the computing system 800 illustrated in FIG. 8, and redundant descriptions for identical components will be omitted. When the direct swap write operation is performed, the host 910 may transmit the first command address signal and then may transmit the second command address signal. The storage memory 932 may output data based on the first command address signal, and the main memory 920 may receive the data output from the storage memory 932 based on the second command address signal. When the direct swap read operation is performed, the host 910 may transmit the second command address signal and then may transmit the first command address signal. The main memory 920 may output data based on the second command address signal, and the storage memory 932 may receive the data output from the main memory 920 based on the first command address signal. In this case, controlling transmission timings of the first and second command address signals and timings of transmitting data output from the storage memory 932 to the main memory 920 or transmitting data output from the main memory 920 to the storage memory 932 individually might not be easy. Therefore, the storage controller 931 may further include a cache 936. The cache 936 may temporarily store the data output from the storage memory 932 and may temporarily store the data output from the main memory 920. During the direct swap write operation, the cache 936 may store the data output from the storage memory 932, and when the main memory 920 is ready to perform the memory write operation, the cache 936 may output the stored data to the main memory controller MMC. During the direct swap read operation, the cache 936 may store the data output from the main memory 920, and when the storage memory 932 is ready to perform the storage write operation, the cache 936 may output the stored data to the storage memory 932. In an embodiment, the cache may be a shared cache, and a region in which the data output from the main memory 920 is stored and a region in which the data output from the storage memory 932 is stored may be separated. In an embodiment, the cache may include a plurality of discrete caches, and the data output from the main memory 920 and the data output from the storage memory 932 may be stored in different discrete caches.

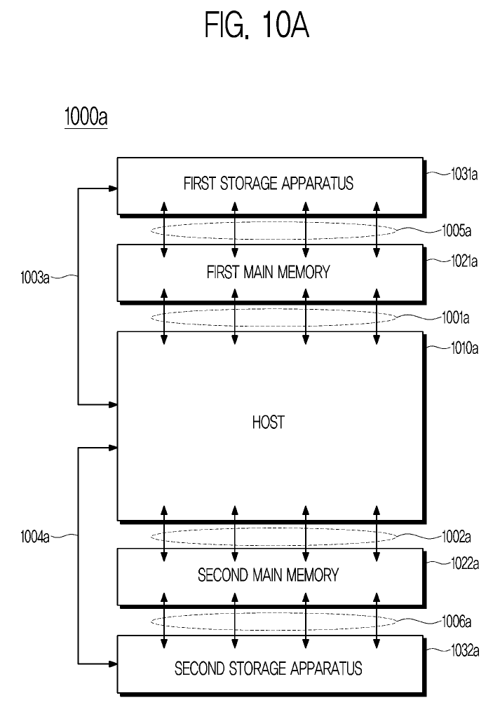

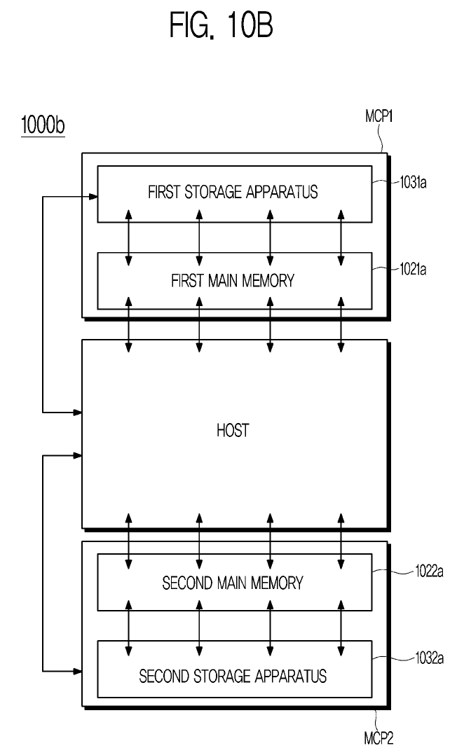

FIGS. 10A and 10B are diagrams illustrating configurations of computing systems 1000a and 1000b, respectively, according to an embodiment of the present disclosure. Referring to FIG. 10A, the computing system 1000a may include a host 1010a, a first main memory 1021a, a second main memory 1022a, a first storage apparatus 1031a, and a second storage apparatus 1032a. The first main memory 1021a may be disposed adjacent to a first side of the host 1010a. The first main memory 1021a may be coupled to the host 1010a through a first memory bus 1001a and may perform data communication with the host 1010a through the first memory bus 1001a. The second main memory 1022a may be disposed adjacent to a second side of the host 1010a, the second side being on the opposite side of the first side. The second main memory 1022a may be coupled to the host 1010a through a second memory bus 1002a and may perform data communication with the host 1010a through the second memory bus 1002a. The first storage apparatus 1031a may be disposed adjacent to the first main memory 1021a, adjacent to a side of the first main memory 1021a that is on the opposite side of the side that is adjacent to the host 1010a. The first storage apparatus 1031a may be coupled to the host 1010a through a first interconnect bus 1003a and may perform data communication with the host 1010a through the first interconnect bus 1003a. The first storage apparatus 1031a may further be coupled to the first main memory 1021a through a third memory bus 1005a. The second storage apparatus 1032a may be disposed adjacent to the second main memory 1022a, adjacent to a side of the second main memory 1022a that is on the opposite side of the side that is adjacent to the host 1010a. The second storage apparatus 1032a may be coupled to the host 1010a through a second interconnect bus 1004a and may perform data communication with the host 1010a through the second interconnect bus 1004a. The second storage apparatus 1032a may further be coupled to the second main memory 1022a through a fourth memory bus 1006a. The first and second interconnect buses 1003a and 1004a may each be the universal storage bus 102 illustrated in FIG. 1. In an embodiment, the first and second interconnect buses 1003a and 1004a may be Peripheral Component Interconnect Express (PCIe). The first main memory 1021a and the first storage apparatus 1031a may be packaged as independent packages, and the second main memory 1022a and the second storage apparatus 1032a may be packaged as separate independent packages.

During the first operation mode, among channels of the first main memory 1021a, channels coupled to the host 1010a through the first memory bus 1001a may be activated, and channels coupled to the first storage apparatus 1031a through the third memory bus 1005a may be deactivated. The first main memory 1021a may receive a first memory command address signal from the host 1010a through the first memory bus 1001a and may perform data communication with the host 1010a based on the first memory command address signal. The first storage apparatus 1031a may receive a first command address signal from the host 1010a through the first interconnect bus 1003a and may perform data communication with the host 1010a based on the first command address signal. Among channels of the second main memory 1022a, channels coupled to the host 1010a through the second memory bus 1002a may be activated, and channels coupled to the second storage apparatus 1032a through the fourth memory bus 1006a may be deactivated. The second main memory 1022a may receive a second memory command address signal from the host 1010a through the second memory bus 1002a and may perform data communication with the host 1010a based on the second memory command address signal. The second storage apparatus 1032a may receive a second command address signal from the host 1010a through the second interconnect bus 1004a and may perform data communication with the host 1010a based on the second command address signal.

The host 1010a may provide an operation mode command signal to the first and second storage apparatuses 1031a and 1032a to change the first operation mode to the second operation mode. During the second operation mode, among channels of the first main memory 1021a, channels coupled to the host 1010a through the first memory bus 1001a may be deactivated, and channels coupled to the first storage apparatus 1031a through the third memory bus 1005a may be activated. The first main memory 1021a might not directly communicate with the host 1010a. The first storage apparatus 1031a may receive the first command address signal and a third command address signal through the first interconnect bus 1003a and may perform data communication with the first main memory 1021a based on the first and third command address signals. The first storage apparatus 1031a may generate a third memory command address signal based on the third command address signal and may provide the third memory command address signal to the first main memory 1021a. Data stored in a storage memory of the first storage apparatus 1031a may be directly moved to the first main memory 1021a through the third memory bus 1005a, and data stored in the first main memory 1021a may be directly moved to the storage memory of the first storage apparatus 1031a through the third memory bus 1005a. Among channels of the second main memory 1022a, channels coupled to the host 1010a through the second memory bus 1002a may be deactivated, and channels coupled to the second storage apparatus 1032a through the fourth memory bus 1006a may be activated. The second main memory 1022a might not directly communicate with the host 1010a. The second storage apparatus 1032a may receive the second command address signal and a fourth command address signal through the second interconnect bus 1004a and may perform data communication with the second main memory 1022a based on the second and fourth command address signals. The second storage apparatus 1032a may generate a fourth memory command address signal based on the fourth command address signal and may provide the fourth memory command address signal to the second main memory 1022a. Data stored in a storage memory of the second storage apparatus 1032a may be directly moved to the second main memory 1022a through the fourth memory bus 1006a, and data stored in the second main memory 1022a may be directly moved to storage memory of the second storage apparatus 1032a through the fourth memory bus 1006a.

The host 1010a may provide an operation mode command signal to the first and second storage apparatuses 1031a and 1032a to change any one of the first and second operation modes to the third operation mode. In the third operation mode, channels of the first main memory 1021a may be coupled to the host 1010a and the first storage apparatus 1031a through the first and third memory buses 1001a and 1005a, respectively. The first main memory 1021a may receive the first memory command address signal from the host 1010a and may perform data communication with the host 1010a based on the first memory command address signal. The first storage apparatus 1031a may receive the first and third command address signals from the host 1010a. The first storage apparatus 1031a may generate the third memory command address signal based on the third command address signal and may provide the third memory command address signal to the first main memory 1021a. Data stored in the storage memory of the first storage apparatus 1031a may be moved to the first main memory 1021a through the third memory bus 1005a, and data stored in the first main memory 1021a may be moved to the storage memory of the first storage apparatus 1031a through the third memory bus 1005a. Channels of the second main memory 1022a may be coupled to the host 1010a and the second storage apparatus 1032a through the second and fourth memory buses 1002a and 1006a, respectively. The second main memory 1022a may receive the second memory command address signal from the host 1010a and may perform data communication with the host 1010a based on the second memory command address signal. The second storage apparatus 1032a may receive the second and fourth command address signals from the host 1010a. The second storage apparatus 1032a may generate the fourth memory command address signal based on the fourth command address signal and may provide the fourth memory command address signal to the second main memory 1022a. Data stored in the storage memory of the second storage apparatus 1032a may be moved to the second main memory 1022a through the fourth memory bus 1006a, and data stored in the second main memory 1022a may be moved to storage memory of the second storage apparatus 1032a through the fourth memory bus 1006a.

Referring to FIG. 10B, the computing system 1000b may include components that are substantially identical to those of the computing system illustrated in FIG. 10A and may perform substantially identical functions and operations. Unlike FIG. 10A, the first main memory 1021b and the first storage apparatus 1031b may be packaged as a single package and may constitute a first multi-chip package MCP1. The second main memory 1022b and the second storage apparatus 1032b may be packaged as a single package and may constitute a second multi-chip package MCP2.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to the provided descriptions. All changes within the meaning and range of equivalency of the claims are included within their scope.

What is claimed is:

1. A computing system comprising:
a host;
a main memory; and
a storage apparatus including a storage memory,
wherein, in a first operation mode, the host performs data communication with the main memory and the storage apparatus, respectively, and in a second operation mode, the host directly moves data between the main memory and the storage memory.

2. The computing system of claim 1, wherein the storage apparatus further comprises a storage controller coupled to the host, the main memory, and the storage memory.

3. The computing system of claim 2, wherein the host is coupled to the main memory through a memory bus and is coupled to the storage controller through a universal storage bus.

4. The computing system of claim 2, wherein the storage controller comprises:
a universal storage controller configured to communicate with the host;
a main memory controller configured to communicate with the main memory; and
a storage memory controller configured to communicate with the storage memory.

5. A computing system comprising:
a host;
a main memory coupled to the host through a first memory bus;
a storage memory; and
a storage controller coupled to the host through a universal storage bus, coupled to the main memory through a second memory bus, and coupled to the storage memory through a storage bus.

6. The computing system of claim 5, wherein the main memory performs data communication with the host through the first memory bus in a first operation mode, and the main memory performs data communication with the storage controller through the second memory bus in a second operation mode.

7. The computing system of claim 5, wherein, in a third operation mode, the main memory performs data communication with the host through the first memory bus and, in parallel, performs data communication with the storage controller through the second memory bus.

8. The computing system of claim 5, wherein the main memory, the storage memory, and the storage controller are packaged as a single package.

9. The computing system of claim 5, wherein the storage controller comprises:
a universal storage controller configured to communicate with the host;
a main memory controller configured to communicate with the main memory; and
a storage memory controller configured to communicate with the storage memory.

10. The computing system of claim 9, wherein the host comprises:
a main memory controller configured to communicate with the main memory; and
a universal storage controller configured to communicate with the storage controller.

11. A computing system comprising:
a host;
a main memory;
a storage memory; and
a storage controller coupled to the host, the main memory, and the storage memory,
wherein the main memory comprises a first memory chip configured to include a first pseudo channel and a second pseudo channel,
wherein pads of the first pseudo channel are coupled to the host, and pads of the second pseudo channel are coupled to the storage controller.

12. The computing system of claim 11, wherein the main memory further comprises a second memory chip configured to include a first pseudo channel and a second pseudo channel, and pads of the first pseudo channel in the second memory chip are coupled to the storage controller and pads of the second pseudo channel in the second memory chip are coupled to the host.

13. The computing system of claim 12, wherein, in a first operation mode, the host is configured to perform a data input/output operation through the pads of the first pseudo channel in the first memory chip and the pads of the second pseudo channel in the second memory chip.

14. The computing system of claim 13, wherein the pads of the first pseudo channel in the first memory chip and the pads of the second pseudo channel in the second memory chip are coupled to the host through a first memory bus.

15. The computing system of claim 13, wherein the pads of the first pseudo channel in the first memory chip and the pads of the second pseudo channel in the second memory chip are coupled to different data buses.

16. The computing system of claim 13, wherein, in a second operation mode, the storage controller is configured to perform a data input/output operation through the pads of the second pseudo channel in the first memory chip and the pads of the first pseudo channel in the second memory chip.

17. The computing system of claim 16, wherein the pads of the second pseudo channel in the first memory chip and the pads of the first pseudo channel in the second memory chip are coupled to the storage controller through a second memory bus.

18. The computing system of claim 17, wherein the pads of the second pseudo channel in the first memory chip and the pads of the first pseudo channel in the second memory chip are coupled to different data buses.

19. The computing system of claim 16, wherein the host is configured to transmit, to the storage controller, a mode command signal that sets the first and second operation modes, and the storage controller is configured to generate a mode signal based on the mode command signal and configured to provide the mode signal to the first and second memory chips.

20. The computing system of claim 19,
wherein the mode signal comprises an input/output mode signal and a channel selection signal;
wherein when the input/output mode signal is at a first logic level, the first pseudo channel and the second pseudo channel of the first memory chip are selected regardless of the channel selection signal;
wherein, when the input/output mode signal is at a second logic level and the channel selection signal is at the first logic level, the first pseudo channel of the first memory chip is selected; and
wherein, when the input/output mode signal is at the second logic level and the channel selection signal is at the second logic level, the second pseudo channel of the first memory chip is selected.

21. The computing system of claim 20,
wherein, when the input/output mode signal is at the first logic level, the first pseudo channel and the second pseudo channel of the second memory chip are selected regardless of the channel selection signal;
wherein, when the input/output mode signal is at the second logic level and the channel selection signal is at the first logic level, the second pseudo channel of the second memory chip is selected; and
wherein, when the input/output mode signal is at the second logic level and the channel selection signal is at the second logic level, the first pseudo channel of the second memory chip is selected.

22. The computing system of claim 12, wherein the main memory is coupled to the host through a first memory bus, and
wherein the storage controller is coupled to the host through a universal storage bus, coupled to the storage memory through a storage bus, and coupled to the main memory through a second memory bus.

23. The computing system of claim 22, wherein the host comprises:
a main memory controller coupled to the first memory bus and configured to communicate with the main memory; and
a universal storage controller coupled to the universal storage bus and configured to communicate with the storage controller.

24. The computing system of claim 22, wherein the storage controller comprises:
a universal storage controller coupled to the universal storage bus and configured to communicate with the host;
a storage memory controller coupled to the storage bus and configured to communicate with the storage memory; and
a main memory controller coupled to the second memory bus and configured to communicate with the main memory.
